(19) United States
(12) Patent Application Publication
(10) Pub. No.: US 2026/0239684 A1
(43) Pub. Date: Aug. 13, 2026

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Syunki NARITA, Matsumoto-city (JP)

(73) Assignee: FUJI ELECTRIC CO., LTD., Kawasaki-shi (JP)

(21) Appl. No.: 19/437,913

(22) Filed: Dec. 31, 2025

(30) Foreign Application Priority Data
Feb. 10, 2025 (JP) 2025-020026

(51) Int. Cl. H10D 62/10; H10D 30/01; H10D 30/66; H10D 62/00; H10D 62/832

(52) U.S. Cl. CPC H10D 62/111; H10D 30/0297; H10D 30/668; H10D 62/052; H10D 62/054; H10D 62/8325

(57) ABSTRACT

A semiconductor device includes: a drift layer including p-type columns and n-type columns alternately and repeatedly arranged; a base region provided on a top surface side of the drift layer; a main region provided on a top surface side of the base region; and an insulated gate electrode structure provided in contact with the base region and the main region, wherein a distribution of an impurity concentration of one of the p-type columns and the n-type columns in a depth direction is constant, and an impurity concentration of another one of the p-type columns and the n-type columns at each of an upper end and a lower end in the depth direction is lower than an average concentration of the other one in the depth direction, and the other one of the p-type columns and the n-type columns has a peak concentration between the upper end and the lower end in the depth direction.

### CROSS-REFERENCE TO RELATED APPLICATION

This application claims benefit of priority under 35 USC 119 based on Japanese Patent Application No. 2025-020026 filed on Feb. 10, 2025, the entire contents of which are incorporated by reference herein.

### BACKGROUND OF THE INVENTION

### 1. Field of the Invention

The present disclosure relates to semiconductor devices and methods of manufacturing the same.

### 2. Description of the Related Art

JP2023-139376A discloses a silicon carbide semiconductor device having a super junction (SJ) structure keeping a charge balance between p-rich on a front-surface side and n-rich on a rear-surface side.

T. Tamaki et al., “Vertical Charge Imbalance Effect on 600 V-class Trench-Filling Superjunction Power MOSFETs”, Proceedings of the 23rd International Symposium on Power Semiconductor Devices & IC's, May 23-26, 2011, San Diego, CA, p. 308-311 discloses a configuration of implementing an SJ structure such that an n-type epitaxial layer is provided with trenches, and the trenches are filled with a p-type epitaxial layer, in which the trenches have a tapered shape in cross section with a width gradually decreased in a depth direction so as to lead a charge balance between an n-type region and a p-type region adjacent to each other in the SJ structure to have a gradient in the depth direction.

Such a conventional SJ structure may cause column widths to fluctuate during manufacturing the SJ structure. The fluctuation of the column widths causes a decrease in breakdown voltage.

### SUMMARY OF THE INVENTION

The present disclosure provides a semiconductor device and a method of manufacturing the same having a configuration capable of avoiding a decrease in breakdown voltage when column widths in an SJ structure fluctuate.

To solve the problems described above, an aspect of the present disclosure inheres in a semiconductor device including: a drift layer including p-type columns and n-type columns alternately and repeatedly arranged; a base region provided on a top surface side of the drift layer; a main region provided on a top surface side of the base region; and an insulated gate electrode structure provided in contact with the base region and the main region, wherein a distribution of an impurity concentration of one of the p-type columns and the n-type columns in a depth direction is constant, and an impurity concentration of another one of the p-type columns and the n-type columns at each of an upper end and a lower end in the depth direction is lower than an average concentration of the other one in the depth direction, and the other one of the p-type columns and the n-type columns has a peak concentration between the upper end and the lower end in the depth direction.

Another aspect of the present disclosure inheres in a method of manufacturing a semiconductor device. the method including: repeatedly executing epitaxial growth of epitaxial growth layers of a first conductivity-type and repeatedly executing ion implantation of impurities of a second conductivity-type so as to form a drift layer including n-type columns and p-type columns alternately and repeatedly arranged, wherein the repeatedly executing the epitaxial growth forms the epitaxial growth layers so as to have thicknesses gradually changed as closer to a top layer, and the repeatedly executing the ion implantation implants the impurities to a common depth.

### BRIEF DESCRIPTION OF THE DRAWINGS

FIG. 1 is a cross-sectional view illustrating an example of a semiconductor device according to a first embodiment;

FIG. 2 is a schematic diagram showing a distribution of a p-type impurity concentration, corresponding to a cross section of a drift layer in the semiconductor device according to the first embodiment;

FIG. 3 is a horizontal cross-sectional view illustrating the example of the semiconductor device according to the first embodiment;

FIG. 4 is a graph showing column-width dependence of breakdown voltage;

FIG. 5 is a cross-sectional process view for explaining an example of a method of manufacturing the semiconductor device according to the first embodiment;

FIG. 6 is a cross-sectional process view, continued from FIG. 5, for explaining the example of the method of manufacturing the semiconductor device according to the first embodiment;

FIG. 7 is a cross-sectional process view, continued from FIG. 6, for explaining the example of the method of manufacturing the semiconductor device according to the first embodiment;

FIG. 8 is a cross-sectional process view, continued from FIG. 7, for explaining the example of the method of manufacturing the semiconductor device according to the first embodiment;

FIG. 9 is a cross-sectional process view, continued from FIG. 8, for explaining the example of the method of manufacturing the semiconductor device according to the first embodiment;

FIG. 10 is a cross-sectional process view, continued from FIG. 9, for explaining the example of the method of manufacturing the semiconductor device according to the first embodiment;

FIG. 11 is a cross-sectional process view, continued from FIG. 10, for explaining the example of the method of manufacturing the semiconductor device according to the first embodiment;

FIG. 12 is a cross-sectional process view, continued from FIG. 11, for explaining the example of the method of manufacturing the semiconductor device according to the first embodiment;

FIG. 13 is a cross-sectional process view, continued from FIG. 12, for explaining the example of the method of manufacturing the semiconductor device according to the first embodiment;

FIG. 14 is a cross-sectional process view, continued from FIG. 13, for explaining the example of the method of manufacturing the semiconductor device according to the first embodiment;

FIG. 15 is a cross-sectional view illustrating a semiconductor device of a comparative example;

FIG. 16 is a cross-sectional process view for explaining a method of manufacturing the semiconductor device of the comparative example;

FIG. 17 is a cross-sectional process view, continued from FIG. 16, for explaining the method of manufacturing the semiconductor device of the comparative example;

FIG. 18 is a cross-sectional process view, continued from FIG. 17, for explaining the method of manufacturing the semiconductor device of the comparative example;

FIG. 19 is a cross-sectional process view, continued from FIG. 18, for explaining the method of manufacturing the semiconductor device of the comparative example;

FIG. 20 is a cross-sectional process view, continued from FIG. 19, for explaining the method of manufacturing the semiconductor device of the comparative example;

FIG. 21 is a cross-sectional process view, continued from FIG. 20, for explaining the method of manufacturing the semiconductor device of the comparative example;

FIG. 22 is a cross-sectional view illustrating an example of a semiconductor device according to a second embodiment;

FIG. 23 is a horizontal cross-sectional view illustrating an example of a semiconductor device according to a third embodiment;

FIG. 24 is a cross-sectional view as viewed from direction A-A in FIG. 23;

FIG. 25 is a cross-sectional view as viewed from direction B-B in FIG. 23;

FIG. 26 is a cross-sectional view illustrating an example of a semiconductor device according to a fourth embodiment;

FIG. 27 is a cross-sectional process view for explaining an example of a method of manufacturing the semiconductor device according to the fourth embodiment;

FIG. 28 is a cross-sectional process view, continued from FIG. 27, for explaining the example of the method of manufacturing the semiconductor device according to the fourth embodiment;

FIG. 29 is a cross-sectional process view, continued from FIG. 28, for explaining the example of the method of manufacturing the semiconductor device according to the fourth embodiment;

FIG. 30 is a cross-sectional process view, continued from FIG. 29, for explaining the example of the method of manufacturing the semiconductor device according to the fourth embodiment;

FIG. 31 is a cross-sectional process view, continued from FIG. 30, for explaining the example of the method of manufacturing the semiconductor device according to the fourth embodiment;

FIG. 32 is a cross-sectional process view, continued from FIG. 31, for explaining the example of the method of manufacturing the semiconductor device according to the fourth embodiment;

FIG. 33 is a cross-sectional process view, continued from FIG. 32, for explaining the example of the method of manufacturing the semiconductor device according to the fourth embodiment; and

FIG. 34 is a cross-sectional process view, continued from FIG. 33, for explaining the example of the method of manufacturing the semiconductor device according to the fourth embodiment.

### DETAILED DESCRIPTION

With reference to the drawings, first to fourth embodiments of the present disclosure will be described below.

In the drawings, the same or similar elements are indicated by the same or similar reference numerals, and overlapping explanations are not repeated.

The drawings are schematic, and it should be noted that the relationship between thickness and planer dimensions, the thickness proportion of each layer, and the like are different from real ones. Moreover, in some drawings, portions are illustrated with different dimensional relationships and proportions.

The first to fourth embodiments described below merely illustrates schematically devices and methods for specifying and giving shapes to the technical idea of the present disclosure, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOSFET transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

Further, the terms “common to”, “the same as”, and “constant” regarding impurity concentrations, widths, depths, thicknesses, or the like as used herein encompass the meanings corresponding to not only strictly “common to”, “the same as”, and “constant” but also encompass a range including a margin of error derived from variations in process that can be substantially regarded as “common to”, “the same as”, and “constant”. The range including a margin of error is plus or minus 10% of the meanings corresponding strictly to “common to”, “the same as”, and “constant”.

### First Embodiment

### Configuration of Semiconductor Device

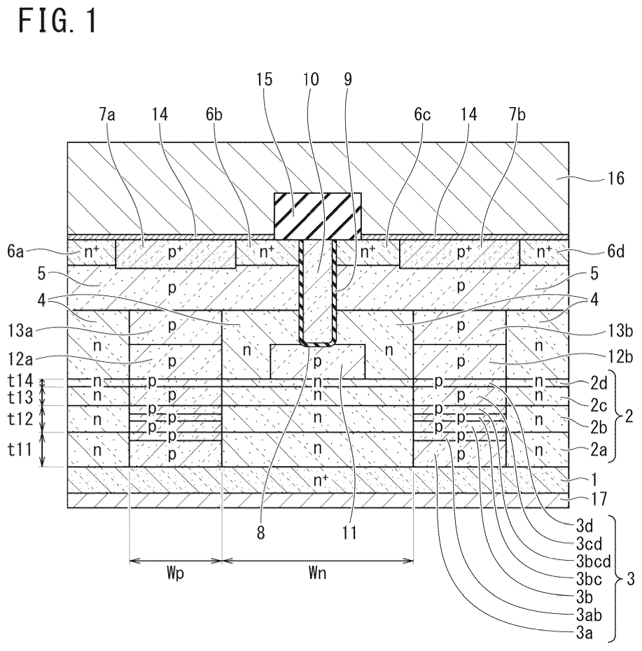

A semiconductor device according to a first embodiment is illustrated below with a silicon carbide (SiC) semiconductor device which is a vertical trench-gate metal-oxide-semiconductor field-effect transistor (MOSFET). While FIG. 1 illustrates a unit cell of the semiconductor device according to the first embodiment, the present embodiment may include a plurality of unit cells arranged parallel to each other so as to implement a multi-channel structure. As illustrated in FIG. 1, the semiconductor device according to the first embodiment includes a main region (a drain region) 1 which is a semiconductor region of a first conductivity-type (n⁺-type). The drain region 1 is a semiconductor substrate (a SiC substrate) including SiC, for example. The drain region 1 has an impurity concentration set in a range of about 1×10¹⁹ cm⁻³ or higher and 3×10²⁰ cm⁻³ or lower, for example.

The semiconductor device according to the first embodiment includes a drift layer (2, 3) on the top surface side of the drain region 1. Any of a buffer layer, a dislocation conversion layer, and a recombination promotion layer, which are each a semiconductor region of n-type having a lower impurity concentration than the drain region 1, may be arranged between the drift layer (2, 3) and the drain region 1.

The drift layer (2, 3) has a super junction (SJ) structure which is a parallel p-n layer including n-type columns 2 and p-type columns 3 alternately and repeatedly arranged in a direction parallel to the top surface of the drain region 1 (in the right-left direction in FIG. 1). The n-type columns 2 and the p-type columns 3 adjacent to each other are in contact with each other. The number of each of the n-type columns 2 and the p-type columns 3 can be determined as appropriate. A width Wn of the respective n-type columns 2 and a width Wp of the respective p-type columns 3 are constant in the depth direction. While FIG. 1 illustrates the case in which the width Wp of the respective p-type columns 3 is smaller than the width Wn of the respective n-type columns 2, the width Wp of the respective p-type columns 3 may be either common to or greater than the width Wn of the respective n-type columns 2.

The respective n-type columns 2 have a constant distribution of an impurity concentration in the depth direction. The impurity concentration in the n-type columns 2 is set in a range of about 1×10¹⁶ cm⁻³ or higher and 1×10¹⁷ cm⁻³ or lower, for example, but is not limited to this range. The respective n-type columns 2 include a plurality of n-type regions 2a to 2d. While FIG. 1 illustrates the case in which the respective n-type columns 2 include the four n-type regions 2a to 2d, the number of the n-type regions included in the n-type columns 2 may be changed as appropriate. For example, the respective n-type columns 2 may include two or three n-type regions, or may include five or more n-type regions instead.

The respective n-type regions 2a to 2d have an impurity concentration common to each other in the depth direction. The n-type regions 2a to 2d have thicknesses t11 to t14 gradually decreased as closer to the top layer. The thicknesses t11 to t14 of the n-type regions 2a to 2d are each set in a range of about 0.3 micrometers or greater and 1.0 micrometers or smaller, for example, but are not limited to this range. While FIG. 1 illustrates the case in which the thicknesses t11 to t14 of the plural n-type regions 2a to 2d are different from each other, the n-type regions 2a to 2d may be arranged to partly have the common thickness next to each other. For example, the thickness t11 of the n-type region 2a may be common to the thickness t12 of the n-type region 2b.

The n-type region 2a located at the lowermost layer of the respective n-type columns 2 is in contact with the top surface of the drain region 1. The n-type region 2a has the thickness t11. The n-type region 2b is provided on the top surface side of the n-type region 2a. The thickness t12 of the n-type region 2b is smaller than the thickness t11 of the n-type region 2a. The n-type region 2c is provided on the top surface side of the n-type region 2b. The thickness t13 of the n-type region 2c is smaller than the thickness t12 of the n-type region 2b. The n-type region 2d is provided on the top surface side of the n-type region 2c. The thickness t14 of the n-type region 2d is smaller than the thickness t13 of the n-type region 2c.

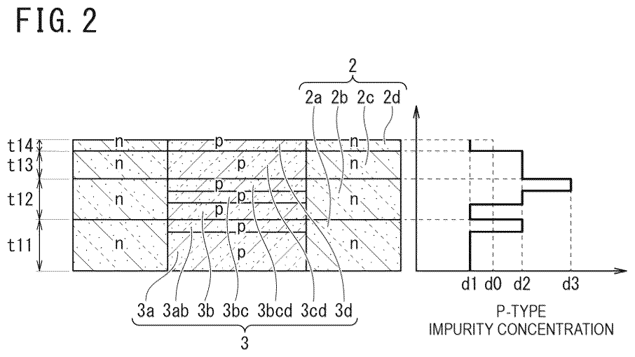

FIG. 2 on the left side selectively illustrates the drift layer (2, 3) in the semiconductor device according to the first embodiment illustrated in FIG. 1. FIG. 2 on the right side shows a distribution of a p-type impurity concentration in the p-type columns 3 in the depth direction. In the distribution of the p-type impurity concentration shown on the right side of FIG. 2, the axis of ordinates shows positions of the p-type columns 3 corresponding to the positions in the drift layer (2, 3) on the left side of FIG. 2, and the axis of abscissas shows the p-type impurity concentration in the respective p-type columns 3. The distribution of the p-type impurity concentration in the p-type columns 3 shown on the right side of FIG. 2 is indicated by the solid line, and an average (an average concentration) d0 of the p-type impurity concentration in the p-type columns 3 in the depth direction is indicated by the broken line.

As shown in FIG. 2, the p-type columns 3 have the distribution of the impurity concentration that varies in the depth direction. The impurity concentration d1 at each of the upper end on the top surface side and the lower end on the bottom surface side of the p-type columns 3 in the depth direction is lower than the average concentration d0 in the p-type columns 3, and is common to each other. A position of the maximum impurity concentration (a peak concentration) d3 in the p-type columns 3 is located between the upper end and the lower end of the p-type columns 3 in the depth direction.

While FIG. 2 illustrates the case in which the position of the peak concentration d of the impurity concentration in the p-type columns 3 is shifted from the middle of the p-type columns 3 in the depth direction so as to be located toward the top surface, the position of the peak concentration d3 of the impurity concentration in the p-type columns 3 may be located in the middle in the depth direction, or may be shifted from the middle so as to be located toward the bottom surface. FIG. 2 also illustrates the case in which the impurity concentration of the p-type columns 3 includes one peak concentration d3, but the impurity concentration may include plural peak concentrations d3 between the upper end and the lower end of the respective p-type columns 3 in the depth direction. Further, FIG. 2 illustrates the case in which the p-type columns 3 have the distribution with the three steps including the impurity concentrations d1 to d3, but the distribution of the impurity concentration may have two steps or four or more steps instead.

As illustrated in FIG. 1 and FIG. 2, the respective p-type columns 3 include a plurality of p-type regions 3a, 3ab, 3b, 3bc, 3bcd, 3cd, and 3d. While FIG. 1 and FIG. 2 each illustrate the case in which the respective p-type columns 3 include the seven p-type regions 3a, 3ab, 3b, 3bc, 3bcd, 3cd, and 3d, the number of the p-type regions included in the p-type columns 3 may be changed as appropriate. For example, the respective p-type columns 3 may include two or more p-type regions and six or less p-type regions, or may include eight or more p-type regions instead.

The bottom surface of the p-type region 3a located at the lowermost layer of the respective p-type columns 3 is in contact with the top surface of the drain region 1. The side surfaces of the p-type region 3a are in contact with the side surfaces at the lower part of the respective n-type regions 2a. The impurity concentration d1 of the p-type region 3a is lower than the average concentration d0, and is the lowest among the impurity concentrations of the p-type regions 3a, 3ab, 3b, 3bc, 3bcd, 3cd, and 3d.

The p-type region 3ab is provided on the top surface side of the p-type region 3a. The side surfaces of the p-type region 3ab are in contact with the side surfaces at the upper part of each n-type region 2a. The impurity concentration d2 of the p-type region 3ab is higher than the average concentration d0.

The p-type region 3b is provided on the top surface side of the p-type region 3ab. The side surfaces of the p-type region 3b are in contact with the side surfaces at the lower part of the respective n-type regions 2b. The impurity concentration d1 of the p-type region 3b is common to the impurity concentration d1 of the p-type region 3a, is lower than the average concentration d0, and is the lowest among the impurity concentrations of the p-type regions 3a, 3ab, 3b, 3bc, 3bcd, 3cd, and 3d.

The p-type region 3bc is provided on the top surface side of the p-type region 3b. The side surfaces of the p-type region 3bc are in contact with the side surfaces of the respective n-type region 2b. The impurity concentration d2 of the p-type region 3bc is common to the impurity concentration d2 of the p-type region 3ab, and is higher than the average concentration d0.

The p-type region 3bcd is provided on the top surface side of the p-type region 3bc. The side surfaces of the p-type region 3bcd are in contact with the side surfaces at the upper part of the respective n-type regions 2b. The impurity concentration d3 of the p-type region 3bcd is maximum, which is the peak concentration among the impurity concentrations of the p-type regions 3a, 3ab, 3b, 3bc, 3bcd, 3cd, and 3d, and is higher than the impurity concentration d2 of the respective p-type regions 3ab and 3bc.

The p-type region 3cd is provided on the top surface side of the p-type region 3bcd. The side surfaces of the p-type region 3cd are in contact with the side surfaces of the respective n-type regions 2c. The impurity concentration d2 of the p-type region 3cd is common to the impurity concentration d2 of the respective p-type regions 3ab and 3bc, and is higher than the average concentration d0.

The p-type region 3d located at the uppermost layer of the respective p-type columns 3 is provided on the top surface side of the p-type region 3cd. The side surfaces of the p-type region 3d are in contact with the side surfaces of the respective n-type regions 2d. The impurity concentration d1 of the p-type region 3d is common to the impurity concentration d1 of the respective p-type regions 3a and 3b, is lower than the average concentration d0, and is the lowest among the impurity concentrations of the p-type regions 3a, 3ab, 3b, 3bc, 3bcd, 3cd, and 3d.

As described above, the drift layer (2, 3) is configured such that the distribution of the impurity concentration in the respective n-type columns 2 is constant in the depth direction, while the distribution of the impurity concentration in the respective p-type columns 3 varies in the depth direction. A charge balance of the drift layer (2, 3) in the depth direction thus has a concentration gradient with relatively p-rich on the top surface side and relatively n-rich on the bottom surface side.

The term “charge balance” refers to an index indicating a degree of balance between a charge amount represented by a product of a carrier concentration (an impurity concentration) in the n-type columns 2 and a width in the thickness direction and a charge amount represented by a product of a carrier concentration in the p-type columns 3 and a width in the depth direction. A sum of the charge amount of the n-type columns 2 may be regulated so as to conform to a sum of the charge amount of the p-type columns 3. The average concentration in the n-type columns 2 in the depth direction may be regulated so as to conform to the average concentration in the p-type columns 3 in the depth direction.

The expression “the concentration gradient with p-rich on the top surface side and n-rich on the bottom surface side ” refers to a case in which the charge amount of the p-type columns 2 relatively leans toward the top surface when the distribution of the impurity concentration in the n-type columns 2 in the depth direction is constant, as in the case of the semiconductor device according to the first embodiment. This case is defined such that the sum of the charge amount of the p-type columns 3 toward the top surface from the middle of the drift layer (2, 3) in the depth direction is set to be greater than the sum of the charge amount of the p-type columns 3 toward the bottom surface from the middle of the drift layer (2, 3) in the depth direction.

When the distribution of the impurity concentration in the p-type columns 3 in the depth direction is constant, the concentration gradient refers to a case in which the charge amount of the n-type columns 2 relatively leans toward the bottom surface This case is defined such that the sum of the charge amount of the n-type columns 2 toward top surface from the middle of the drift layer (2, 3) in the depth direction is set to be smaller than the sum of the charge amount of the n-type columns 2 toward the bottom surface from the middle of the drift layer (2, 3) in the depth direction.

As illustrated in FIG. 1, a current spreading layer (CSL) 4, which is a semiconductor region of a first conductivity-type (n-type) including SiC and having a higher impurity concentration than the n-type columns 2 of the drift layer (2, 3), is provided on the top surface side of the drift layer (2, 3). The impurity concentration of the current spreading layer 4 is set in a range of about 5×10¹⁶ cm⁻³ or higher and 5×10¹⁷ cm⁻³ or lower, for example.

A base region 5 which is a semiconductor device of a second conductivity-type (p-type) including SiC is provided on the top surface side of the current spreading layer 4. The base region 5 has an impurity concentration set in a range of about 1×10¹⁷ cm⁻³ or higher and 1×10¹⁸ cm⁻³ or lower, for example.

First main regions (source regions) 6a to 6d, which are each a semiconductor region of the first conductivity-type (n⁺-type) including SiC and having a higher impurity concentration than the n-type columns 2 of the drift layer (2, 3), are provided on the top surface side of the base region 5. The impurity concentration of the respective source regions 6a to 6d is set in a range of about 1×10¹⁷ cm⁻³ or higher and 5×10¹⁸ cm⁻³ or lower, for example.

Base contact regions 7a and 7b, which are each a semiconductor region of the second conductivity-type (p⁺-type) including SiC and having a higher impurity concentration than the base region 5, are provided on the top surface side of the base region 5 so as to be in contact with the base region 5 and the source regions 6a to 6d. While FIG. 1 illustrates the case in which the base contact regions 7a and 7b each have a greater depth than the source regions 6a to 6d, the depth of the respective base contact regions 7a and 7b may be either common to or shallower than that of the respective source regions 6a to 6d. The impurity concentration of the base contact regions 7a and 7b is set in a range of about 5×10¹⁹ cm⁻³ or higher and 5×10²⁰ cm⁻³ or lower, for example.

Trenches 8 are dug downward from the top surfaces of the source regions 6a to 6d to penetrate the source regions 6a to 6d and the base region 5 in the depth direction normal to the top surface of the respective source regions 6a to 6d. The respective bottom surfaces of the trenches 8 reach the current spreading layer 4. The respective side surfaces of the trenches 8 are in contact with the source regions 6a to 6d, the base region 5, and the current spreading layer 4.

The trenches 8 each have a width in a range of about 0.3 micrometers or greater and 1.0 micrometers or smaller, for example. A depth d1 of the respective trenches 8 is set in a range of about 0.7 micrometers or greater and 1.3 micrometers or smaller, and may be set to about 1 micrometer, for example. While FIG. 1 illustrates the case in which the side surfaces of the trenches 8 are vertical flat surfaces, the respective side surfaces of the trenches 8 may define a tapered shape to make either a trapezoid or an inverted trapezoid in cross section, or may be a curved surface convex outward. In addition, FIG. 1 illustrates the case in which the bottom surfaces of the trenches 8 are flat surfaces, but the respective bottom surfaces of the trenches 8 may be a curved surface convex downward. Further, a corner part between the bottom surface and the side surface of the respective trenches 8 may have a curvature.

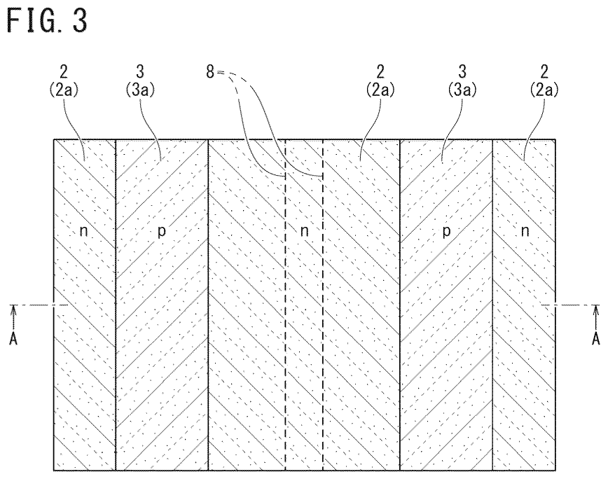

FIG. 3 is a horizontal cross-sectional view as viewed from the top surface side taken along the plane passing through the n-type region 2a at the lowermost layer of the n-type columns 2 and the p-type region 3a at the lowermost layer of the p-type columns 3 in the drift layer (2, 3) illustrated in FIG. 1. The vertical cross section taken along line A-A in FIG. 3 as viewed from the lower side to the upper side in FIG. 2 corresponds to FIG. 1. FIG. 3 schematically indicates, by the broken lines, the position of the trench 8 located over the n-type region 2a.

As illustrated in FIG. 3, the trench 8 has a straight (stripe-shaped) planar pattern extending in one direction (the upper-lower direction in FIG. 3). The n-type columns 2 and the p-type columns 3 have a straight (stripe-shaped) planar pattern extending parallel to the trench 8.

As illustrated in FIG. 1, a gate insulating film 9 is provided along the bottom and side surfaces of the respective trenches 8. A gate electrode 10 is buried inside the respective trenches 8 with the gate insulating film 9 interposed. The gate insulating film 9 and the gate electrode 10 implement a trench-gate insulated gate electrode structure (9, 10).

The gate insulating film 9 as used herein can be a single-layer film of a silicon oxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or may be a composite film including some of the above films stacked on one another. The gate electrode 10 may be implemented by a polysilicon layer (a doped polysilicon layer) heavily doped with p-type impurities or n-type impurities, or may include refractory metal, such as titanium (Ti), tungsten (W), and nickel (Ni).

An insulating film 15 which is an interlayer insulating film is provided on the top surface side of the gate electrode 10. The insulating film 15 as used herein can be a single-layer film such as a silicon oxide film (a SiO₂ film) without containing impurities, which is referred to as a non-doped silicate glass (NSG) film, a phosphosilicate glass film (a PSG film), a borosilicate glass film (a BSG film), a borophosphosilicate glass film (a BPSG film), or a silicon nitride film (a Si₃N₄ film), or can be a composite film including some of the above films combined together.

A first main electrode (a source electrode) (14, 16) is provided on the top surface side of the source regions 6a to 6d and the base contact regions 7a and 7b so as to be in contact with each other. The source electrode (14, 16) is provided separately from a gate electrode (not illustrated) electrically connected to the gate electrode 10. The source electrode (14, 16) includes a source contact layer 14 provided in contact with the respective top surfaces of the source regions 6a to 6d and the base contact regions 7a and 7b, and a source electrode layer 16 provided in contact with the top surface of the source contact layer 14. The source contact layer 14 includes nickel silicide (NiSix), for example. The source electrode layer 16 is provided to cover the insulating film 15. The source electrode layer 16 includes metal such as aluminum (Al) and copper (Cu), or an alloy such as aluminum-silicon (Al—Si) and aluminum-copper (Al—Cu), for example.

A barrier metal layer including metal such as titanium nitride (TiN) and titanium (Ti), or metal having a stacked structure of TiN/Ti including Ti as a lower layer may be provided between the source contact layer 14 and the source electrode layer 16. A plug layer including tungsten (W) or the like may be provided between the barrier metal layer and the source electrode layer 16.

A gate-bottom protection region 11 which is a semiconductor region of the second conductivity-type (p-type) including SiC is provided under the bottom surface side of the respective trenches 8 inside the current spreading layer 4. The gate-bottom protection region 11 has a function capable of relaxing an electric field applied to the gate insulating film 9 provided on the bottom surface of the respective trenches 8. The gate-bottom protection region 11 has an impurity concentration set in a range of about 1×10¹⁷ cm⁻³ or higher and 1×10¹⁹ cm⁻³ or lower, for example. The gate-bottom protection region 11 may be electrically connected to the base region 5 on the either frontward or backward side of the sheet of FIG. 1.

While FIG. 1 illustrates the case in which the gate-bottom protection region 11 i in contact with the bottom surface of the trench 8, the gate-bottom protection region 11 may be provided separately from the respective bottom surfaces of the trenches 8. Further, FIG. 1 illustrates the case in which the gate-bottom protection region 11 has a width greater than the width of the respective trenches 8, but the width of the gate-bottom protection region 11 may be either common to or smaller than the width of the respective trenches 8. The provision of the gate-bottom protection region 11 is optional.

Lower-side buried regions 12a and 12b which are each a semiconductor region of the second conductivity-type (p-type) including SiC are provided inside the current spreading layer 4 respectively under the base contact regions 7a and 7b. The lower-side buried regions 12a and 12b are provided separately from the gate-bottom protection region 11. The respective lower-side buried regions 12a and 12b have a higher impurity concentration than the base region 5, which is set in a range of about 5×10¹⁷ cm⁻³ or higher and 2×10¹⁹ cm⁻³ or lower, for example.

Upper-side buried regions 13a and 13b which are each a semiconductor region of the second conductivity-type (p-type) including SiC are provided on the top surface sides of the lower-side buried regions 12a and 12b inside the current spreading layer 4 under the base contact regions 7a and 7b. The respective top surfaces of the upper-side buried regions 13a and 13b are in contact with the bottom surface of the base region 5. The respective upper-side buried regions 13a and 13b have a higher impurity concentration than the base region 5, which is set in a range of about 1×10¹⁸ cm⁻³ or higher and 1×10¹⁹ cm⁻³ or lower, for example.

The p-type columns 3 of the drift layer (2, 3) are located immediately under the lower-side buried regions 12a and 12b. The top surfaces of the uppermost p-type regions 3d included in the p-type columns 3 are in contact with the respective bottom surfaces of the lower-side buried regions 12a and 12b. The p-type columns 3 are electrically connected to the base contact regions 7a and 7b via the lower-side buried regions 12a and 12b, the upper-side buried regions 13a and 13b, and the base region 5.

A second main electrode (a drain electrode) 17 is provided on the bottom surface side of the drain region 1. The drain electrode 17 may be a single-layer film including gold (Au) or a metal film including titanium (Ti), nickel (Ni), and Au sequentially stacked together from the drain region 1, and may be further provided with a metal film including molybdenum (Mo) and tungsten (W) as a lowermost layer. A silicide layer including nickel silicide (NiSiₓ) may be arranged between the drain region 1 and the drain electrode 17 so as to ensure an ohmic contact.

The semiconductor device according to the first embodiment during a switching operation applies a positive voltage to the drain electrode 17 with the source electrode (14, 16) used as an earth potential, and also applies a positive voltage of a threshold or greater to the gate electrode 10. This operation provides inversion layers (channels) in a region of the base region 5 in contact with the gate insulating film 9 so as to lead the vertical MOSFET to be in an ON-state. In the ON-state, a current flows from the drain electrode 17 toward the source electrode (14, 16) through the drain region 1, the drift layer (2, 3), the inversion layers in the base region 5, and the source regions 6a to 6d. When the voltage applied to the gate electrode 10 is less than the threshold, the vertical MOSFET is led to be in an OFF-state while no current flows from the drain electrode 17 toward the source electrode (14, 16), since no inversion layers are formed in the base region 5. The provision of the drift layer (2, 3) with the SJ structure can reduce ON-resistance.

The semiconductor device according to the first embodiment has the configuration, as described above, in which the drift layer (2, 3) has the SJ structure, and the distribution of the n-type impurity concentration in the n-type columns 2 is constant in the depth direction, while the distribution of the p-type impurity concentration in the p-type columns 3 varies in the depth direction. This configuration can lead the charge balance between the n-type columns 2 and the p-type columns 3 adjacent to each other to have a gradient. A reduction in breakdown voltage thus can be avoided if the width Wp of the p-type columns 3 and the width Wn of the n-type columns 2 fluctuate.

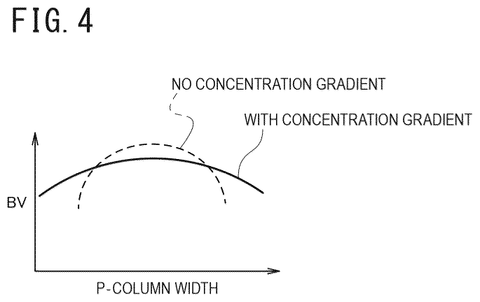

FIG. 4 shows column-width dependency of breakdown voltage in the case in which the charge balance between the n-type columns 2 and the p-type columns 3 of the drift layer (2, 3) in the depth direction has a gradient, as compared with a comparative example in which the charge balance between the n-type columns 2 and the p-type columns 3 in the depth direction has no gradient. The axis of abscissas in FIG. 4 indicates a p-type column width, and the axis of ordinates in FIG. 4 indicates breakdown voltage (BV). As shown in FIG. 4, the configuration in which the charge balance between the n-type columns 2 and the p-type columns 3 has the gradient in the depth direction (indicated as “with concentration gradient” by the solid line) can increase a breakdown-voltage margin if the p-type column width fluctuates, as compared with the configuration in which the charge balance between the n-type columns 2 and the p-type columns 3 has no gradient in the depth direction (indicated as “no concentration gradient” by the broken line).

### Method of Manufacturing Semiconductor Device

An example of a method of manufacturing the semiconductor device according to the first embodiment illustrated in FIG. 1 is described below with reference to FIG. 1 and FIG. 5 to FIG. 14.

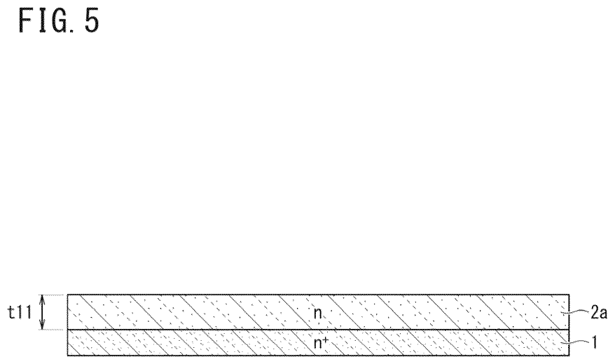

First, a semiconductor substrate (a SiC substrate) 1 of n⁺-type including SiC and doped with n-type impurities such as nitrogen (N) is prepared (refer to FIG. 5). The top surface of the SiC substrate 1 has an off-angle in a range of about three degrees or greater and eight degrees or smaller from a [0001] plane.

Next, the drift layer (2, 3) with the SJ structure is formed on the top surface side o the SiC substrate 1 by a multi-step epitaxial process. The multi-step epitaxial process repeatedly executes epitaxial growth of epitaxial growth layers and ion implantation of impurities having a conductivity-type opposite to that of the epitaxial growth layers, so as to form the columns having one of the conductivity-types partly in the epitaxial growth layers while forming the other columns in the rest of the epitaxial growth layers. In the step of forming the drift layer (2, 3) in the semiconductor device according to the first embodiment, the plural epitaxial growth steps form the epitaxial growth layers so as to have thicknesses gradually decreased as closer to the top layer. In addition, the ion implantation is executed with the ion implantation conditions fixed for each of the ion implantation steps for forming the respective epitaxial growth layers.

In particular, as illustrated in FIG. 5, an epitaxial growth layer 2a of n-type including SiC is epitaxially grown as a first layer (a first stage) on the top surface of the SiC substrate 1 so as to have a thickness t11.

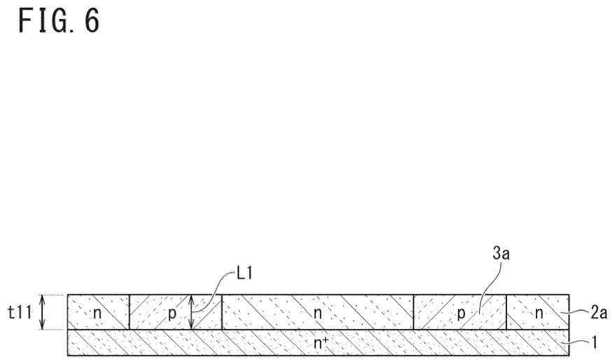

Next, a mask for ion implantation made of a photoresist film or the like is formed on the top surface side of the epitaxial growth layer 2a by photolithography. A first step of implanting p-type impurity ions (also referred to below as “first ion implantation”) is executed under predetermined ion implantation conditions by use of the mask for ion implantation. The mask for ion implantation is then removed. This step also selectively forms the p-type regions 3a which are each a semiconductor region of p-type including SiC partly in the epitaxial growth layer 2a through the implantation of the p-type impurity ions by the first ion implantation, as illustrated in FIG. 6. This step further selectively forms the n-type regions 2a which are each a semiconductor region of n-type including SiC in the rest of the epitaxial growth layer 2a not provided with the p-type regions 3a.

The ion implantation conditions for the first ion implantation include a predetermined ion species, a predetermined acceleration voltage, and a predetermined dose. The predetermined ion species is the p-type impurities such as aluminum (Al) and boron (B). A range L1, which is a depth of the first ion implantation, can be adjusted in accordance with the predetermined acceleration voltage. While FIG. 6 illustrates the case in which the range L1 of the first ion implantation is common to the thickness t11 of the n-type regions 2a, the range L1 may be greater than or equal to the thickness t11 of the epitaxial growth layers 2a.

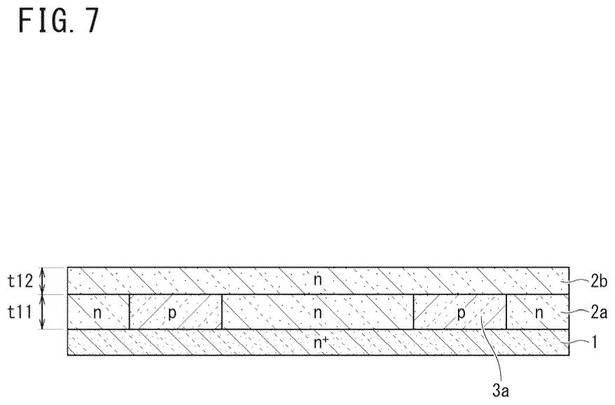

Next, as illustrated in FIG. 7, an epitaxial growth layer 2b which is a semiconductor region of n-type including SiC is epitaxially grown as a second layer (a second stage) on the top surface side of the n-type regions 2a and the p-type regions 3a. A thickness t12 of the epitaxial growth layer 2b is smaller than the thickness t11 of each of the n-type regions 2a and the p-type regions 3a. The epitaxial growth layer 2b has an impurity concentration common to that of the n-type regions 2a.

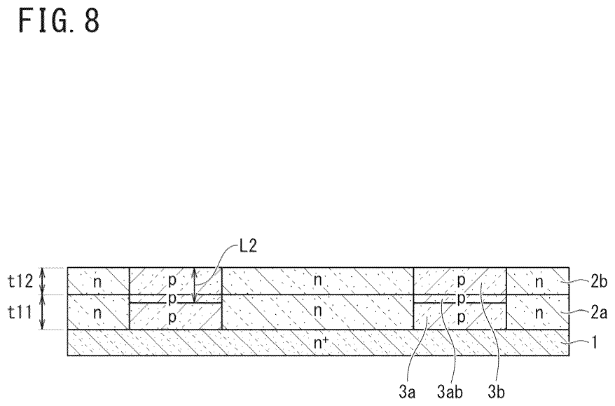

Next, a mask for ion implantation made of a photoresist film or the like is formed on the top surface side of the epitaxial growth layer 2b by photolithography. Openings of the mask for ion implantation are provided to be located over the respective p-type regions 3a. Next, a second step of implanting p-type impurity ions (also referred to below as “second ion implantation”) is executed by use of the mask for ion implantation. The ion implantation conditions for the second ion implantation are common to those for the first ion implantation. A range L2 of the second ion implantation (refer to FIG. 8) is common to the range L1 of the first ion implantation, but the range L2 has a depth greater than the thickness t12 of the epitaxial growth layer 2b to reach the upper part of the p-type regions 3a, since the thickness t12 of the epitaxial growth layer 2b is smaller than the thickness t11 of the epitaxial growth layer 2a. The p-type impurity ions are thus implanted by the second ion implantation partly in the same p-type regions 3a as the implantation of the p-type impurity ions by the first ion implantation prior to this ion implantation. The mask for ion implantation is then removed.

This step forms the p-type regions 3ab, which are each a semiconductor region of p-type including SiC, having a higher impurity concentration than the p-type regions 3a and doped with the p-type impurities accumulated together through the first and second ion implantation steps at the upper part of the p-type regions 3a, as illustrated in FIG. 8. This step also selectively forms the p-type regions 3b which are each a semiconductor region of p-type including SiC partly in the epitaxial growth layer 2b through the implantation of the p-type impurities by the second ion implantation. This step further selectively forms the n-type regions 2b which are each a semiconductor region of n-type including SiC in the rest of the epitaxial growth layer 2b not provided with the p-type regions 3b.

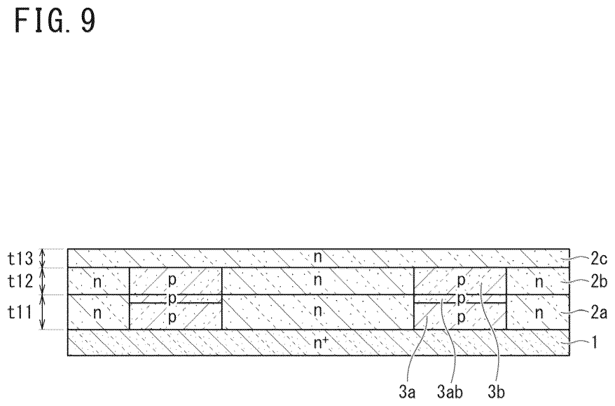

Next, as illustrated in FIG. 9, an epitaxial growth layer 2c which is a semiconductor region of n-type including SiC is epitaxially grown as a third layer (a third stage) on the top surface side of the n-type regions 2b and the p-type regions 3b. A thickness t13 of the epitaxial growth layer 2c is smaller than the thickness t12 of each of the n-type regions 2b and the p-type regions 3b. The epitaxial growth layer 2c has an impurity concentration common to that of the n-type regions 2a and 2b.

Next, a mask for ion implantation made of a photoresist film or the like is formed on the top surface side of the epitaxial growth layer 2c by photolithography. Openings of the mask for ion implantation are provided to be located over the respective p-type regions 3b. Next, a third step of implanting p-type impurity ions (also referred to below as “third ion implantation”) is executed by use of the mask for ion implantation. The ion implantation conditions for the third ion implantation are common to those for the first and second ion implantation steps. A range L3 of the third ion implantation is common to the range L1 of the first ion implantation and the range L2 of the second ion implantation, but the range L3 has a depth greater than the thickness t13 of the epitaxial growth layer 2c to reach the upper part of the p-type regions 3b, since the thickness t13 of the epitaxial growth layer 2c is smaller than the thickness t12 of the epitaxial growth layer 2b. The p-type impurity ions are thus implanted by the third ion implantation partly in the same p-type regions 3b as the implantation of the p-type impurity ions by the second ion implantation prior to this ion implantation. The mask for ion implantation is then removed.

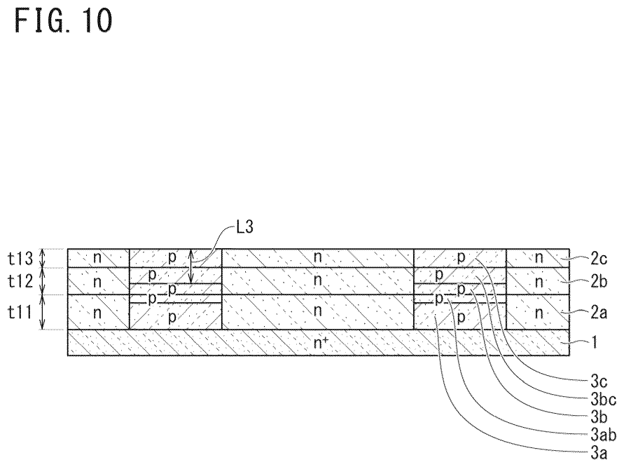

This step forms the p-type regions 3bc, which are each a semiconductor region of p-type including SiC, having a higher impurity concentration than the p-type regions 3b and doped with the p-type impurities accumulated together through the first to third ion implantation steps at the upper part of the p-type regions 3b, as illustrated in FIG. 10. This step also selectively forms the p-type regions 3c which are each a semiconductor region of p-type including SiC partly in the epitaxial growth layer 2c through the implantation of the p-type impurity ions by the third ion implantation. This step further selectively forms the n-type regions 2c which are each a semiconductor region of n-type including SiC in the rest of the epitaxial growth layer 2c not provided with the p-type regions 3c.

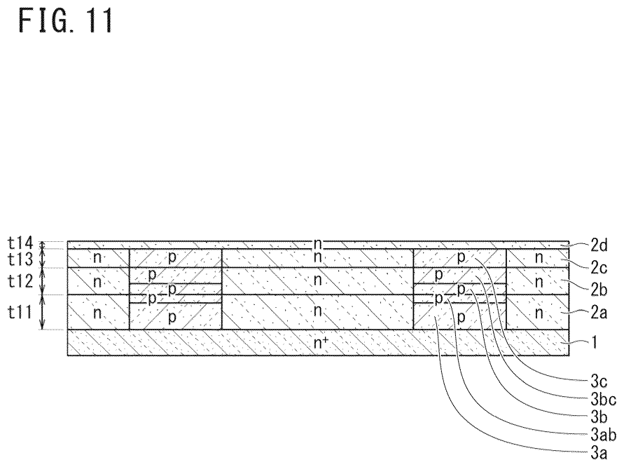

Next, as illustrated in FIG. 11, an epitaxial growth layer 2d which is a semiconductor region of n-type including SiC is epitaxially grown as a fourth layer (a fourth stage) on the top surface side of the n-type regions 2c and the p-type regions 3c. A thickness t14 of the epitaxial growth layer 2d is smaller than the thickness t13 of each of the n-type regions 2c and the p-type regions 3c. The epitaxial growth layer 2d has an impurity concentration common to that of the n-type regions 2a to 2c.

Next, a mask for ion implantation made of a photoresist film or the like is formed on the top surface side of the epitaxial growth layer 2d by photolithography. Openings of the mask for ion implantation are provided to be located over the respective p-type regions 3c. Next, a fourth step of implanting p-type impurity ions (also referred to below as “fourth ion implantation”) is executed by use of the mask for ion implantation. The ion implantation conditions for the fourth ion implantation are common to those for the first to third ion implantation steps. A range L4 of the fourth ion implantation is common to the ranges L1 to L3 of the first to third ion implantation steps, but the range L4 has a depth greater than the sum of the thickness t14 of the epitaxial growth layer 2d and the thickness t13 of the respective n-type regions 2c to reach the upper part of the p-type regions 3bc, since the thickness t14 of the epitaxial growth layer 2d is smaller than the thickness t13 of the epitaxial growth layer 2c. The p-type impurity ions are thus implanted by the fourth ion implantation partly in the same p-type regions 3bc and 3c as the implantation of the p-type impurity ions by the third ion implantation prior to this ion implantation. The mask for ion implantation is then removed.

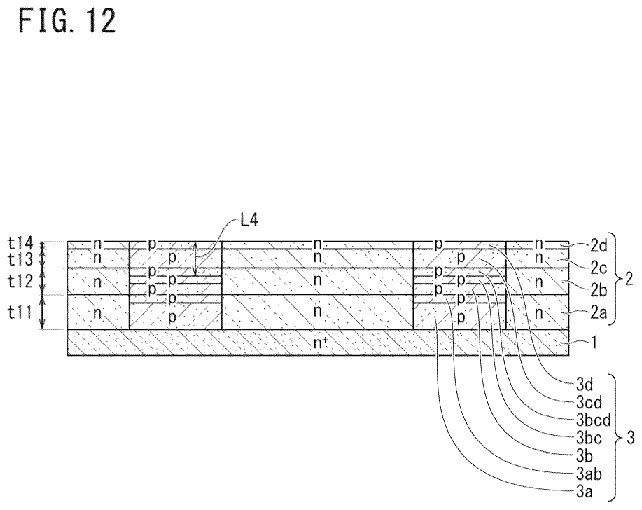

This step forms the p-type regions 3bcd, which are each a semiconductor region of p-type including SiC, having a higher impurity concentration than the p-type regions 3bc and doped with the p-type impurities accumulated together through the second to fourth ion implantation steps at the upper part of the p-type regions 3bc, as illustrated in FIG. 12. This step also forms the p-type regions 3cd, which are each a semiconductor region of p-type including SiC, having a higher impurity concentration than the p-type regions 3c and doped with the p-type impurities accumulated together through the third and fourth ion implantation steps in the p-type regions 3c. This step also selectively forms the p-type regions 3d which are each a semiconductor region of p-type including SiC partly in the epitaxial growth layer through the implantation of the p-type impurities by the fourth ion implantation. This step further selectively forms the n-type regions 2d which are each a semiconductor region of n-type including SiC in the rest of the epitaxial growth layer 2d not provided with the p-type regions 3d.

The drift layer (2, 3) with the SJ structure is thus formed in which the n-type columns 2 and the p-type columns 3 are repeatedly arranged in parallel. The distribution of the impurity concentration in the n-type columns 2 is constant in the depth direction, while the distribution of the impurity concentration in the p-type columns 3 varies in the depth direction. The respective n-type columns 2 include the plural n-type regions 2a to 2d. The respective p-type columns 3 include the plural p-type regions 3a, 3ab, 3b, 3bc, 3bcd, 3cd, and 3d.

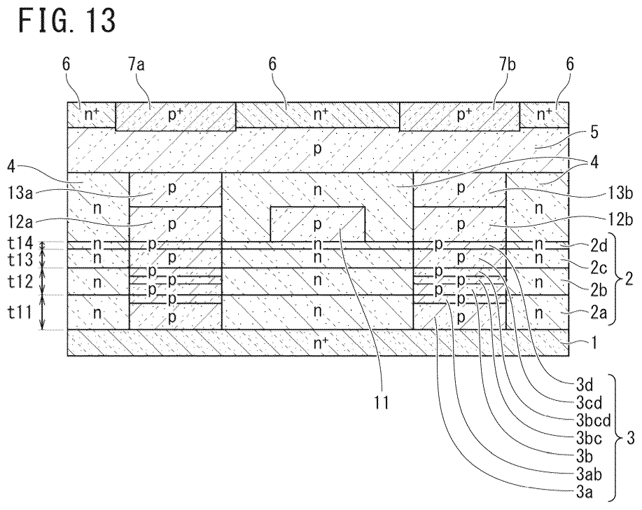

Next, an epitaxial growth layer which is a semiconductor region of n-type including SiC is epitaxially grown as a lower part of the current spreading layer 4 on the top surface of the drift layer (2, 3). Next, the p-type lower-side buried regions 12a and 12b and the p-type gate-bottom protection region 11 (refer to FIG. 13) are selectively formed in a part of the n-type epitaxial growth layer by photolithography, ion implantation, and the like. Next, an epitaxial growth layer which is a semiconductor region of n-type including SiC is epitaxially grown as an upper part of the current spreading layer 4 on the top surfaces of the n-type epitaxial growth layer, the lower-side buried regions 12a and 12b, and the gate-bottom protection region 11, so as to form the current spreading layer 4 (refer to FIG. 13). Next, the p-type upper-side buried regions 13a and 13b (refer to FIG. 13) are selectively formed in a part of the current spreading layer 4 by photolithography and ion implantation, for example.

Next, the base region 5 (refer to FIG. 13) which is a semiconductor region of p-type including SiC is epitaxially grown on the top surface sides of the current spreading layer 4 and the upper-side buried regions 13a and 13b. Next, the source region 6 which is a semiconductor region of n⁺-type including SiC and the base contact regions 7a and 7b which are each a semiconductor region of p⁺-type including SiC are selectively formed at the upper part of the base region 5 by photolithography, ion implantation, and the like, as illustrated in FIG. 13.

Next, thermal treatment (activation annealing) is executed, so as to simultaneously activate the p-type impurity ions and the n-type impurity ions implanted into the gate-bottom protection region 11, the lower-side buried regions 12a and 12b, the upper-side buried regions 13a and 13b, the source region 6, the base regions 7a and 7b, and the like. While the present embodiment illustrates the case of executing the simultaneous single activation annealing after the execution of all of the ion implantation steps, plural activation annealing steps may be executed independently after the respective ion implantation steps.

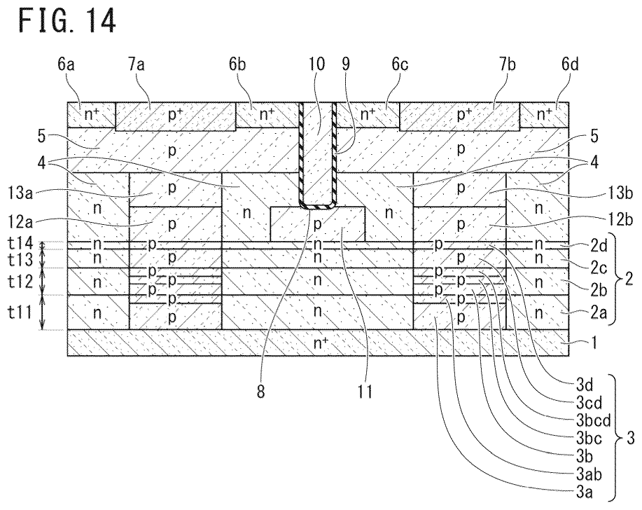

Next, the trenches 8 (refer to FIG. 14) are selectively provided from the top surface of the source region 6 in the depth direction by photolithography, dry etching, and the like. The trenches 8 penetrate the source region 6 and the base region 5, and further dig the upper part of the current spreading layer 4 to reach the gate-bottom protection region 11. The source region 6 is defined by the trenches 8 to be divided into the source regions 6a to 6d (refer to FIG. 14). The trenches 8 do not necessarily reach the gate-bottom protection region 11, but are only required to reach the current spreading layer 4.

Next, the gate insulating film 9 (refer to FIG. 14) is formed along the bottom and side surfaces of the trenches 8 and the respective top surfaces of the source regions 6a to 6d and the base contact regions 7a and 7b by thermal oxidation, CVD, or the like. Next, a polysilicon layer (a doped polysilicon layer) heavily doped with impurities such as phosphorus (P) and boron (B) is deposited so as to fill the inside of the respective trenches 8 by CVD or the like. A part of the polysilicon layer is then selectively removed by photolithography and dry etching. This step provides the insulated gate electrode structure (9, 10) including the gate insulating film 9 and the gate electrode 10, as illustrated in FIG. 14.

Next, the insulating film 15 (refer to FIG. 1) which is an interlayer insulating film is deposited on the top surface side of the insulated gate electrode structure (9, 10) by CVD or the like. The insulating film 15 and the gate insulating film 9 are then partly and selectively removed by photolithography and dry etching, for example, so as to open contact holes in the insulating film 15 to which the respective top surfaces of the source regions 6a to 6d and the base contact regions 7a and 7b are exposed. This step may be followed by thermal treatment (reflowing) for flattening the insulating film 15.

Next, the source contact layer 14 (refer to FIG. 1) in contact with the respective top surfaces of the source regions 6a to 6d and the base contact regions 7a and 7b, and the source electrode layer 16 (refer to FIG. 1) on the top surface side of the source contact layer 14 are sequentially formed by sputtering, vapor deposition, or the like, so as to form the source electrode (14, 16).

Next, the SiC substrate 1 is ground from the bottom surface side by grinding, chemical mechanical polishing (CMP), or the like to decrease and adjust the thickness so as to obtain the drain region 1. Thereafter, the drain electrode 17 (refer to FIG. 1) including titanium (Ti), nickel (Ni), and gold (Au) is formed on the entire bottom surface of the drain region 1 by sputtering or vapor deposition, for example. The silicon carbide semiconductor device illustrated in FIG. 1 is thus completed through the above procedure.

The method of manufacturing the silicon carbide semiconductor device according to the first embodiment as described above forms the drift layer (2, 3) with the SJ structure through the multi-step epitaxial growth process. This process forms the n-type epitaxial growth layers 2a to 2d with the thicknesses gradually decreased as closer to the top layer, and uses the fixed depth in the plural steps for implanting the p-type impurity ions. This can provide the drift layer (2, 3) with the SJ structure having a concentration gradient with p-rich on the top surface side and n-rich on the bottom surface side.

### Comparative Example

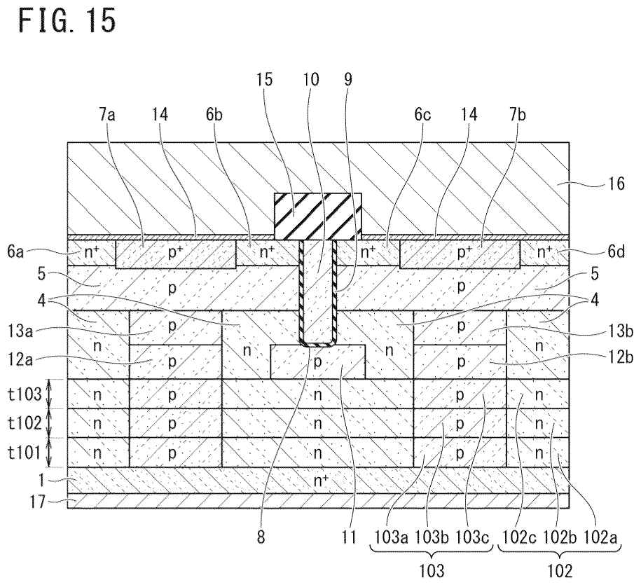

A semiconductor device of a comparative example is described below. The semiconductor device of the comparative example differs from the silicon carbide semiconductor device according to the first embodiment in a structure regarding a drift layer (102, 103) having an SJ structure, as illustrated in FIG. 15.

The drift layer (102, 103) includes n-type columns 102 and p-type columns 103. A distribution of an impurity concentration in the n-type columns 102 in the depth direction is constant. The n-type columns 102 include a plurality of n-type regions 102a to 102c. The n-type regions 102a to 102c respectively have thicknesses t101 to t103 which are common to each other. The respective n-type regions 102a to 102c have the common impurity concentration.

A distribution of an impurity concentration in the p-type columns 103 in the depth direction varies. The p-type columns 103 include a plurality of p-type regions 103a to 103c. The p-type regions 103a to 103c have impurity concentrations gradually increased as closer to the top layer.

A method of preparing the drift layer (102, 103) of the semiconductor device of the comparative example is described below. The method of preparing the drift layer (102, 103) of the semiconductor device of the comparative example is the same as the method of preparing the drift layer (2, 3) of the silicon carbide semiconductor device according to the first embodiment in using the multi-step epitaxial growth process. The method of preparing the drift layer (102, 103) of the semiconductor device of the comparative example differs from the method of preparing the drift layer (2, 3) of the silicon carbide semiconductor device according to the first embodiment in that the thicknesses of the epitaxial growth layers grown through the plural epitaxial growth steps are fixed, and the ion implantation conditions for the plural ion implantation steps need to be regulated.

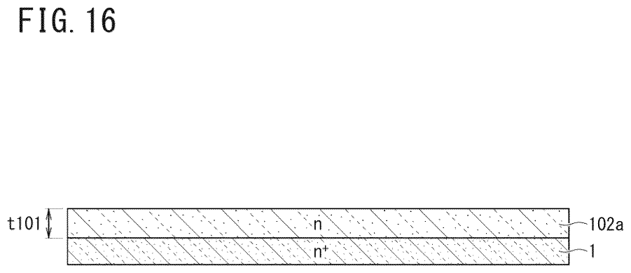

In particular, the method of preparing the drift layer (102, 103) of the semiconductor device of the comparative example grows an epitaxial growth layer 102a of n-type with a thickness t101 on the top surface of the SiC substrate 1, as illustrated in FIG. 16.

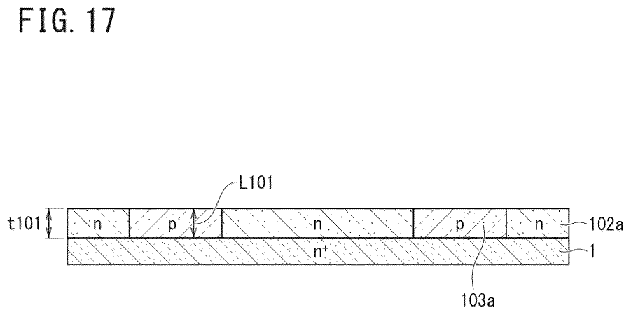

Next, a first step of implanting p-type impurity ions is executed, as illustrated in FIG. 17. A range L101 of the first ion implantation is common to the thickness t101 of the epitaxial growth layer 102a. This step selectively forms the p-type regions 103a partly in the epitaxial growth layer 102a through the implantation of the p-type impurity ions by the first ion implantation, and also forms the n-type regions 102a in the rest of the epitaxial growth layer 102a.

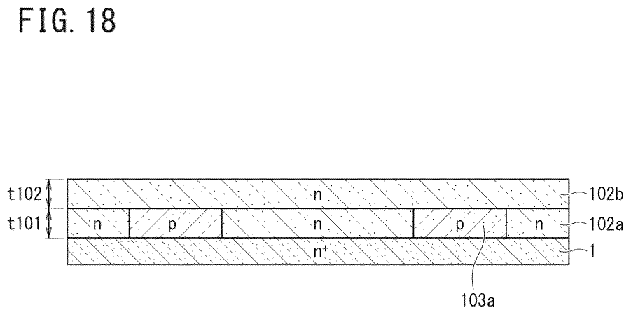

Next, as illustrated in FIG. 18, an epitaxial growth layer 102b of n-type is grown with a thickness t102 on the respective top surfaces of the n-type regions 102a and the p-type regions 103a.

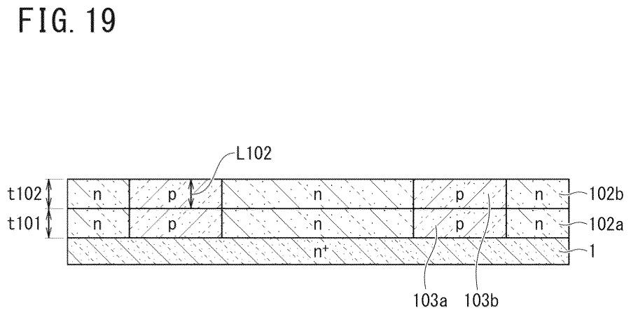

Next, a second step of implanting p-type impurity ions is executed, as illustrated in FIG. 19. A range L102 of the second ion implantation is common to the range L101 of the first ion implantation, and is common to the thickness t102 of the epitaxial growth layer 102b. A dose in the second ion implantation is greater than that in the first ion implantation. This step selectively forms the p-type regions 103b having a higher impurity concentration than the p-type regions 103a partly in the epitaxial growth layer 102b through the implantation of the p-type impurity ions by the second ion implantation, and also forms the n-type regions 102b in the rest of the epitaxial growth layer 102b.

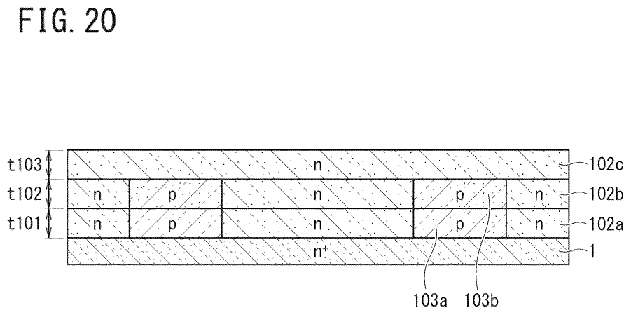

Next, as illustrated in FIG. 20, an epitaxial growth layer 102c of n-type is grown with a thickness t103 on the respective top surfaces of the n-type regions 102b and the p-type regions 103b.

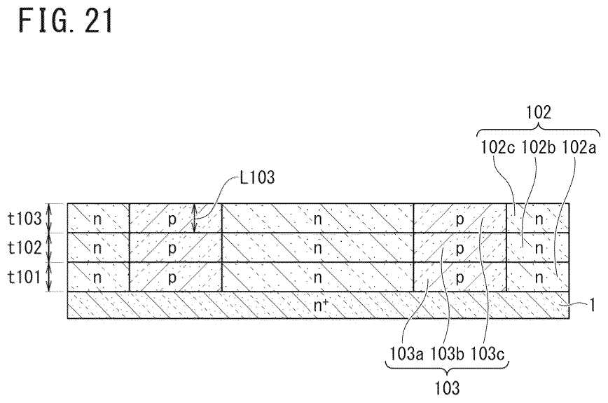

Next, a third step of implanting p-type impurity ions is executed, as illustrated in FIG. 21. A range L103 of the third ion implantation is common to the range L101 of the first ion implantation and the range L102 of the second ion implantation, and is also common to the thickness t103 of the epitaxial growth layer 102c. A dose of the p-type impurity ions in the third ion implantation is greater than that in the second ion implantation. This step selectively forms the p-type regions 103c having a higher impurity concentration than the p-type regions 103b partly in the epitaxial growth layer 102c through the implantation of the p-type impurity ions by the third ion implantation, and also forms the n-type regions 102c in the rest of the epitaxial growth layer 102c. The drift layer (102, 103) of the semiconductor device of the comparative example is thus formed through the above process.

The method of preparing the drift layer (102, 103) of the semiconductor device of the comparative example needs to change the dose of the impurity ions in each of the first to third ion implantation steps in order to provide the gradient in the charge balance between the n-type columns 102 and the p-type columns 103 in the depth direction. In contrast, the manufacturing method for the semiconductor device according to the first embodiment leads the thicknesses t1 to t4 of the n-type epitaxial growth layers 2a to 2d to vary so as to be gradually decreased as closer to the top layer in the respective epitaxial growth steps. This method can fix the ion implantation conditions for the plural ion implantation steps, which does not require an extra process for regulating the ion implantation conditions. Further, this method can avoid a division of the p-type columns 3 in the upper-lower direction regardless of the use of SiC which tends to impede a diffusion of implanted ions, so as to stabilize the switching operations accordingly.

### Second Embodiment

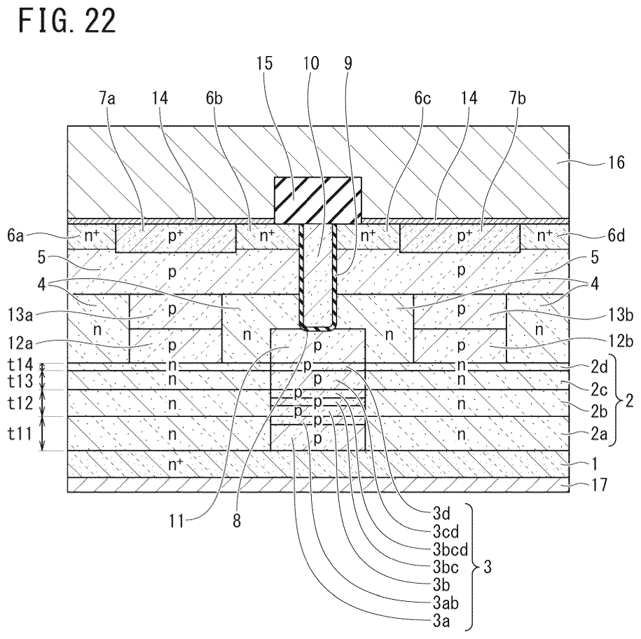

A semiconductor device according to a second embodiment illustrated in FIG. 22 differs from the semiconductor device according to the first embodiment in the positions of the n-type columns 2 and the p-type columns 3 of the drift layer (2, 3). The semiconductor device according to the second embodiment has a configuration in which the respective p-type columns 3 of the drift layer (2, 3) are located immediately under the p-type gate-bottom protection region 11. The top surface of the p-type region 3d at the uppermost layer of the respective p-type columns 3 is in contact with the bottom surface of the gate-bottom protection region 11.

The other configurations of the semiconductor device according to the second embodiment are substantially the same as those of the semiconductor device according to the first embodiment, and overlapping explanations are not repeated below. A method of manufacturing the semiconductor device according to the second embodiment is substantially common to the method of manufacturing the semiconductor device according to the first embodiment, except for providing the n-type columns 2 and the p-type columns 3 of the drift layer (2, 3) in the different positions, and overlapping explanations are not repeated below.

The configuration of the semiconductor device and the manufacturing method according to the second embodiment provide the drift layer (2, 3) with the SJ structure, set the distribution of the impurity concentration of the n-type impurities in the n-type columns 2 in the depth direction to be constant, and cause the distribution of the impurity concentration of the p-type impurities in the p-type columns 3 in the depth direction to vary, so as to provide a gradient in the charge balance between the n-type columns 2 and the p-type columns 3 in the depth direction, as in the case of the semiconductor device and the manufacturing method according to the first embodiment. This can increase a breakdown-voltage margin if the width of the p-type columns 3 and the width of the n-type columns 2 each fluctuate.

### Third Embodiment

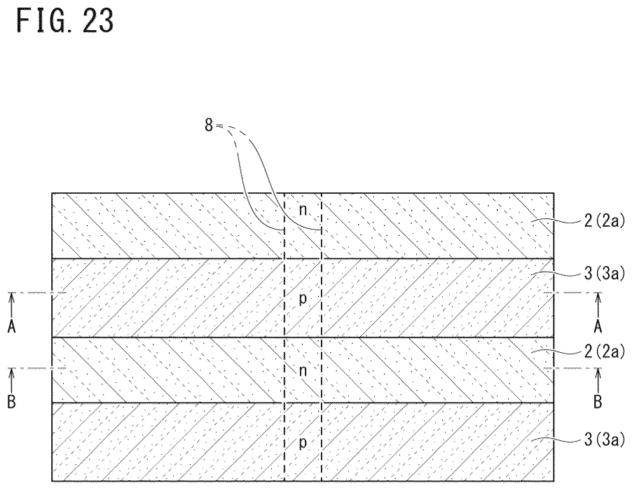

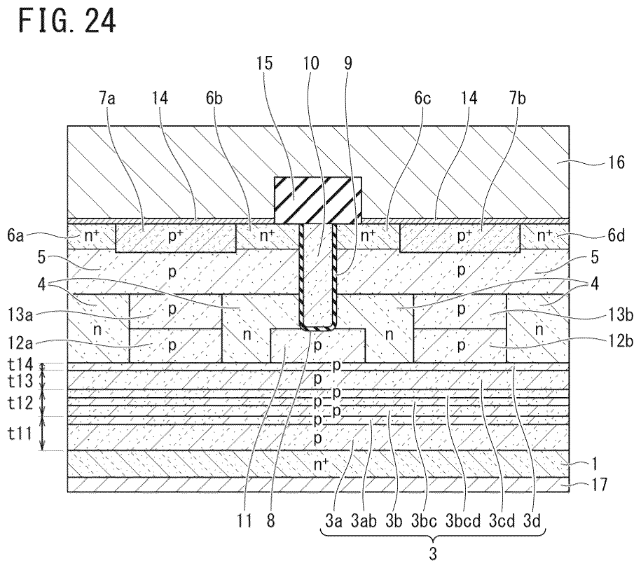

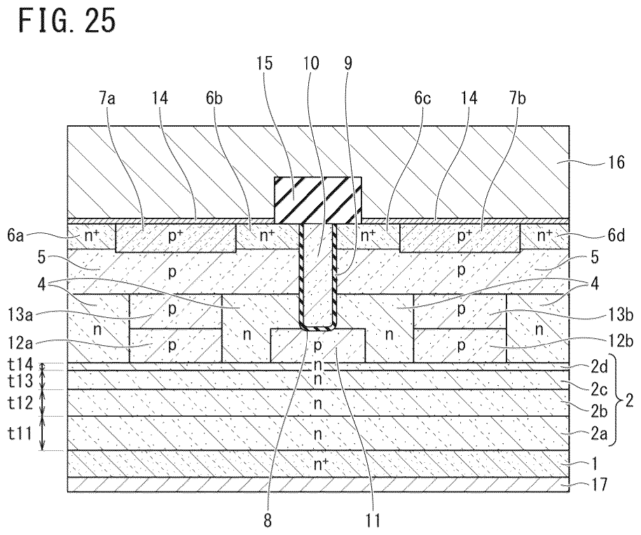

FIG. 23 is a horizontal cross-sectional view passing through the lowermost n-type regions 2a of the n-type columns 2 and the lowermost p-type regions 3a of the p-type columns 3 in the drift layer (2, 3) in a semiconductor device according to a third embodiment, corresponding to the horizontal cross section of the semiconductor device according to the first embodiment illustrated in FIG. 3. FIG. 23 schematically indicates, by the broken lines, the position of the trench 8 located over the n-type columns 2 and the p-type columns 3. FIG. 24 is a vertical cross-sectional view as viewed from direction A-A in FIG. 23. FIG. 25 is a vertical cross-sectional view as viewed from direction B-B in FIG. 23.

The semiconductor device according to the third embodiment differs from the semiconductor device according to the first embodiment in that the n-type columns 2 and the p-type columns 3 of the drift layer (2, 3) each have a planar pattern extending in a direction orthogonal to (intersecting) the extending direction of the trenches 8, as illustrated in FIG. 23 to FIG. 25. As illustrated in the cross-sectional view of FIG. 24, the top surface of the p-type region 3d located at the uppermost layer of the respective p-type columns 3 is in contact with the respective bottom surfaces of the current spreading layer 4, the gate-bottom protection region 11, and the lower-side buried regions 12a and 12b. As illustrated in the cross-sectional view of FIG. 25, the top surface of the n-type region 2d located at the uppermost layer of the respective n-type columns 2 is in contact with the respective bottom surfaces of the current spreading layer 4, the gate-bottom protection region 11, and the lower-side buried regions 12a and 12b.

The other configurations of the semiconductor device according to the third embodiment are substantially the same as those of the semiconductor device according to the first embodiment, and overlapping explanations are not repeated below. A method of manufacturing the semiconductor device according to the third embodiment is substantially common to the method of manufacturing the semiconductor device according to the first embodiment, except for providing the n-type columns 2 and the p-type columns 3 of the drift layer (2, 3) in the different positions, and overlapping explanations are not repeated below.

The configuration of the semiconductor device and the manufacturing method according to the third embodiment provide the drift layer (2, 3) with the SJ structure, set the distribution of the impurity concentration of the n-type impurities in the n-type columns 2 in the depth direction to be constant, and cause the distribution of the impurity concentration of the p-type impurities in the p-type columns 3 in the depth direction to vary, so as to provide a gradient in the charge balance between the n-type columns 2 and the p-type columns 3 in the depth direction, as in the case of the semiconductor device and the manufacturing method according to the first embodiment. This can increase a breakdown-voltage margin if the width of the p-type columns 3 and the width of the n-type columns 2 each fluctuate.

### Fourth Embodiment

### Configuration of Semiconductor Device

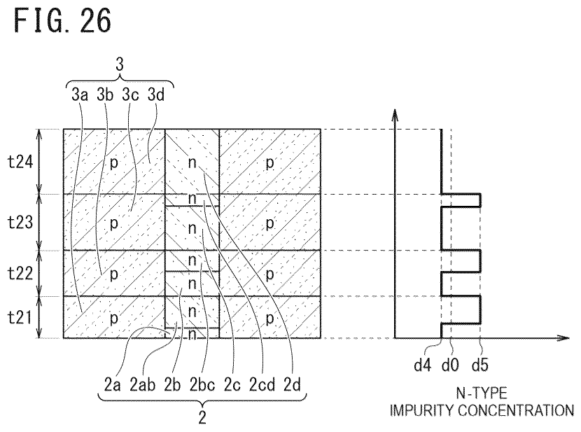

FIG. 26 on the left side selectively illustrates a part of the drift layer (2, 3) in a semiconductor device according to a fourth embodiment. The semiconductor device according to the fourth embodiment differs from the semiconductor device according to the first embodiment in that the p-type columns 3 of the drift layer (2, 3) have a distribution of an impurity concentration that is constant in the depth direction, while the n-type columns 2 have a distribution of an impurity concentration that varies in the depth direction. Namely, the present embodiment may have the configuration in which the distribution of the impurity concentration in either the p-type columns 3 or the n-type columns 2 is constant in the depth direction, while the distribution of the impurity concentration in the other ones varies in the depth direction. The other configurations of the semiconductor device according to the fourth embodiment are substantially the same as those of the semiconductor device according to the first embodiment except for the drift layer (2, 3), and overlapping explanations are not repeated below.

FIG. 26 on the right side shows the distribution of the n-type impurity concentration in the n-type columns 2 in the depth direction. In the distribution of the n-type impurity concentration shown on the right side of FIG. 26, the axis of ordinates shows a depth position of the n-type columns 2, and the axis of abscissas shows the n-type impurity concentration. The distribution of the n-type impurity concentration in the n-type columns 2 in the depth direction shown on the right side of FIG. 26 is indicated by the solid line, and an average (an average concentration) d0 of the n-type impurity concentrations in the n-type columns 2 in the depth direction is indicated by the broken line.

The drift layer (2, 3) has an SJ structure in which the n-type columns 2 and the p-type columns 3 are alternately and repeatedly arranged parallel to each other. The width of the p-type columns 3 and the width of the n-type columns 2 are each constant in the depth direction.

The distribution of the impurity concentration in the p-type columns 3 is constant in the depth direction. The respective p-type columns 3 include a plurality of p-type regions 3a to 3d. While FIG. 26 illustrates the case in which the respective p-type columns 3 include the four p-type regions 3a to 3d, the number of the p-type regions included in the respective p-type columns 3 may be changed as appropriate. For example, the respective p-type columns 3 may include two or three p-type regions, or may include five or more p-type regions instead.

The respective p-type regions 3a to 3d have an impurity concentration common to each other in the depth direction. The p-type regions 3a to 3d have thicknesses t21 to t24 gradually increased as closer to the top layer. While FIG. 26 illustrates the case in which the thicknesses of the p-type regions 3a to 3d are gradually increased as closer to the top layer, the p-type regions 3a to 3d may be arranged to partly have the common thickness next to each other. For example, the thickness t21 of the p-type region 3a may be common to the thickness t22 of the p-type region 3b.

The p-type region 3a located at the lowermost layer of the respective p-type columns 3 has the thickness t21. The p-type region 3b is provided on the top surface side of the p-type region 3a. The thickness t22 of the p-type region 3b is greater than the thickness t21 of the p-type region 3a. The p-type region 3c is provided on the top surface side of the p-type region 3b. The thickness t23 of the p-type region 3c is greater than the thickness t22 of the p-type region 3b. The p-type region 3d located at the uppermost layer of the respective p-type columns 3 is provided on the top surface side of the p-type region 3c. The thickness t24 of the p-type region 3d is greater than the thickness t23 of the p-type region 3c.

While FIG. 26 illustrates the case in which the n-type columns 2 have the distribution of the impurity concentration in the depth direction with the two steps including the impurity concentrations d4 and d5, the distribution of the impurity concentration may have three or more steps. The upper end on the top surface side and the lower end on the bottom surface side of the n-type columns 2 in the depth direction have the common impurity concentration d4, which is lower than the average concentration d0. The maximum impurity concentration (the peak concentration) d5 in the n-type columns 2 in the depth direction is located between the upper end and the lower end of the n-type columns 2. While FIG. 26 illustrates the case in which the impurity concentration in the n-type columns 2 includes three peak concentrations d5, the impurity concentration may include one or two peaks, or may include four or more peaks.

The respective n-type columns 2 include the plural n-type regions 2a, 2ab, 2b, 2bc, 2c, 2cd, and 2d. While FIG. 26 illustrates the case in which the respective n-type columns 2 include the seven n-type regions 2a, 2ab, 2b, 2bc, 2c, 2cd, and 2d, the number of the n-type regions included in the n-type columns 2 may be changed as appropriate. The respective n-type columns 2 may include two or more n-type regions and six or less n-type regions, or may include eight or more n-type regions instead.

The side surfaces of the n-type region 2a at the lowermost layer of the respective n-type columns 2 are in contact with the side surfaces at the lower part of the respective p-type regions 3a. The impurity concentration d4 of the n-type region 2a is lower than the average concentration d0. The n-type region 2ab is provided on the top surface side of the n-type region 2a. The side surfaces of the n-type region 2ab are in contact with the side surfaces at the upper part of the respective p-type regions 3a. The impurity concentration d5 of the n-type region 2ab is higher than the average concentration d0.

The n-type region 2b is provided on the top surface side of the n-type region 2ab. The side surfaces of the n-type region 2b are in contact with the side surfaces at the lower part of the respective p-type region 3b. The impurity concentration d4 of the n-type region 2b is common to the impurity concentration d4 of the n-type region 2a, and is lower than the average concentration d0. The n-type region 2bc is provided on the top surface side of the n-type region 2b. The side surfaces of the n-type region 2bc are in contact with the side surfaces at the upper part of the respective p-type region 3b. The impurity concentration d5 of the n-type region 2bc is common to the impurity concentration d5 of the n-type region 2ab, and is higher than the average concentration d0.

The n-type region 2c is provided on the top surface side of the n-type region 2bc. The side surfaces of the n-type region 2c are in contact with the side surfaces at the lower part of the respective p-type region 3c. The impurity concentration d4 of the n-type region 2c is common to the impurity concentration d4 of the n-type regions 2a and 2b, and is lower than the average concentration d0. The n-type region 2cd is provided on the top surface side of the n-type region 2c. The side surfaces of the n-type region 2cd are in contact with the side surfaces at the upper part of the respective p-type region 3c. The impurity concentration d5 of the n-type region 2cd is common to the impurity concentration d5 of the n-type regions 2ab and 2bc, and is higher than the average concentration d0.

The n-type region 2d is provided on the top surface side of the n-type region 2cd. The side surfaces of the n-type region 2d are in contact with the respective p-type regions 3d. The impurity concentration d4 of the n-type region 2d is common to the impurity concentration d4 of the n-type regions 2a to 2c, and is lower than the average concentration d0.

As described above, the distribution of the impurity concentration in the p-type columns 3 of the drift layer (2, 3) is set to be constant in the depth direction, while the distribution of the impurity concentration in the n-type columns 2 is led to vary in the depth direction. The sum of the charge amount of the n-type columns 2 toward the bottom surface from the middle of the drift layer (2, 3) in the depth direction is greater than the sum of the charge amount of the n-type columns 2 toward the top surface from the middle of the drift layer (2, 3) in the depth direction, so as to provide a concentration gradient with p-rich on the top surface side and n-rich on the bottom surface side. The sum of the charge amount of the p-type columns 3 in the depth direction may be regulated in the same manner as the sum of the charge amount of the n-type columns 2 in the depth direction. The average concentration of the impurity concentrations of the p-type columns 3 in the depth direction may be regulated in the same manner as the average concentration of the impurity concentrations of the n-type columns 2 in the depth direction.

The configuration of the semiconductor device according to the fourth embodiment sets the distribution of the p-type impurity concentration in the p-type columns 3 in the depth direction to be constant, and causes the distribution of the n-type impurity concentration in the n-type columns 2 in the depth direction to vary in the drift layer (2, 3) with the SJ structure, so as to provide a gradient in the charge balance between the n-type columns 2 and the p-type columns 3 in the depth direction. This can increase a breakdown-voltage margin if the width of the n-type columns 2 and the width of the p-type columns 3 each fluctuate.

### Method of Manufacturing Semiconductor Device

An example of a method of manufacturing the semiconductor device according to the fourth embodiment is described below with reference to FIG. 26 to FIG. 34. The method of manufacturing the semiconductor device according to the fourth embodiment is substantially common to the method of manufacturing the semiconductor device according to the first embodiment, except for the preparation of the drift layer (2, 3). The specific preparation method for the drift layer (2, 3) is only described below, while overlapping explanations are not repeated below.

The preparation method for the drift layer (2, 3) in the semiconductor device according to the fourth embodiment forms the drift layer (2, 3) with the SJ structure on the top surface of the SiC substrate 1 by a multi-step epitaxial process. The multi-step epitaxial process is executed such that epitaxial growth of a p-type epitaxial growth layer and ion implantation of n-type impurities are repeated several times. The epitaxial growth executed repeatedly forms the p-type epitaxial growth layers so as to have thicknesses gradually increased as closer to the top surface. The ion implantation of the n-type impurities executed repeatedly implants the n-type impurity ions in the same depth while using the same ion impurity conditions.

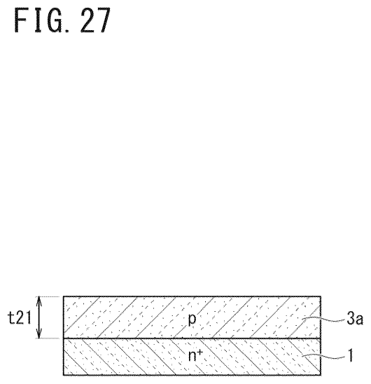

In particular, as illustrated in FIG. 27, an epitaxial growth layer 3a of p-type including SiC is epitaxially grown as a first layer (a first stage) with a thickness t21 on the top surface side of the n⁺-type semiconductor substrate (the SiC substrate) 1 including SiC.

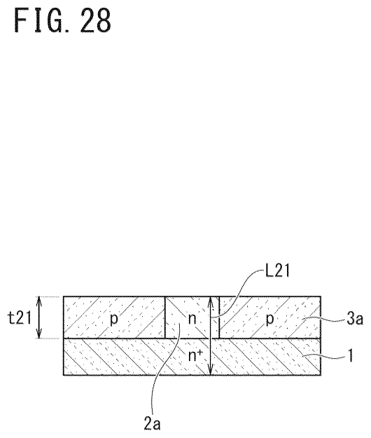

Next, a mask for ion implantation made of a photoresist film or the like is formed on the top surface side of the epitaxial growth layer 3a by photolithography. Next, a first step of implanting n-type impurity ions such as phosphorus (P) and nitrogen (N) (also referred to below as “first ion implantation”) is executed under predetermined ion implantation conditions by use of the mask for ion implantation. The predetermined ion implantation conditions include a predetermined ion species, a predetermined acceleration voltage, and a predetermined dose. A range L21 (refer to FIG. 28) which is a depth of the first ion implantation can be adjusted in accordance with the predetermined acceleration voltage. The range L21 of the first ion implantation is greater than the thickness t21 of the epitaxial growth layer 3a. The mask for ion implantation is then removed.

This step selectively forms the n-type regions 2a which are each a semiconductor region of n-type including SiC partly in the epitaxial growth layer 3a through the implantation of the n-type impurity ions by the first ion implantation, as illustrated in FIG. 28. This step further selectively forms the p-type regions 3a which are each a semiconductor region of p-type including SiC in the rest of the epitaxial growth layer 3a not provided with the n-type regions 2a.

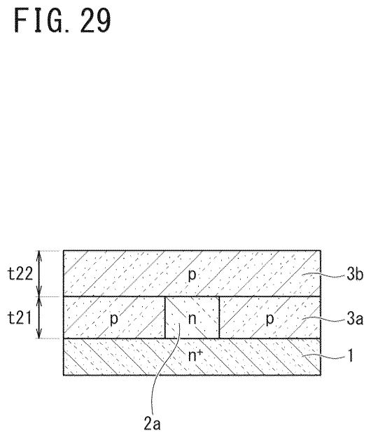

Next, as illustrated in FIG. 29, an epitaxial growth layer 3b which is a semiconductor region of p-type including SiC is epitaxially grown as a second layer (a second stage) on the top surface side of the n-type regions 2a and the p-type regions 3a. A thickness t22 of the epitaxial growth layer 3b is greater than the thickness t21 of each of the n-type regions 2a and the p-type regions 3a. The epitaxial growth layer 3b has an impurity concentration common to that of the n-type region 3a.

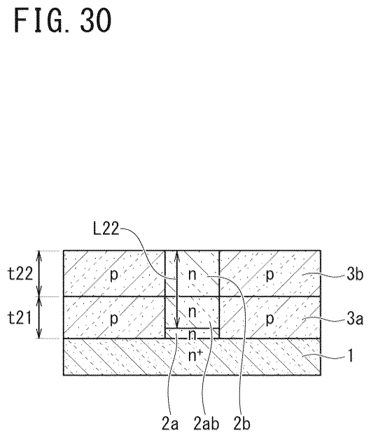

Next, a mask for ion implantation made of a photoresist film or the like is formed on the top surface side of the epitaxial growth layer 3b by photolithography. Openings of the mask for ion implantation are provided to be located over the respective n-type regions 2a. Next, a second step of implanting n-type impurity ions (also referred to below as “second ion implantation”) is executed by use of the mask for ion implantation. The ion implantation conditions for the second ion implantation are common to those for the first ion implantation step. A range L22 of the second ion implantation (refer to FIG. 30) is greater than the thickness t22 of the epitaxial growth layer 3b to reach the upper part of the n-type regions 2a, since the thickness t22 of the epitaxial growth layer 3b is greater than the thickness t21 of the n-type regions 2a, but does not reach the bottom surface of the n-type regions 2a. The n-type impurity ions are thus implanted by the second ion implantation in the respective upper parts of the same n-type regions 2a as the implantation of the n-type impurity ions by the first ion implantation. The mask for ion implantation is then removed.

This step forms the n-type regions 2ab, which are each a semiconductor region of n-type including SiC, having a higher impurity concentration than the n-type regions 2a and doped with the n-type impurities accumulated together through the first and second ion implantation steps at the upper part of the n-type regions 2a, as illustrated in FIG. 30. This step also selectively forms the n-type regions 2b which are each a semiconductor region of n-type including SiC partly in the epitaxial growth layer 3b through the implantation of the n-type impurity ions by the second ion implantation. This step further selectively forms the p-type regions 3b which are a semiconductor region of p-type including SiC in the rest of the epitaxial growth layer 3b not provided with the n-type regions 2b.

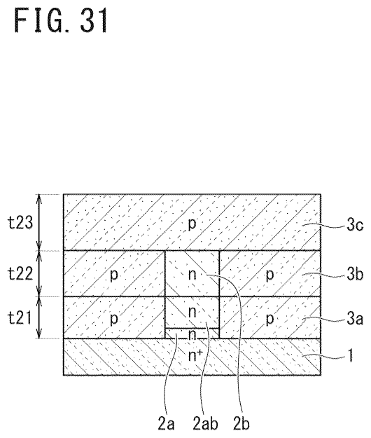

Next, as illustrated in FIG. 31, an epitaxial growth layer 3c which is a semiconductor region of p-type including SiC is epitaxially grown as a third layer (a third stage) on the top surface side of the n-type regions 2b and the p-type regions 3b. A thickness t23 of the epitaxial growth layer 3c is greater than the thickness t22 of each of the n-type regions 2b and the p-type regions 3b. The epitaxial growth layer 3c has an impurity concentration common to that of the n-type region 3b.

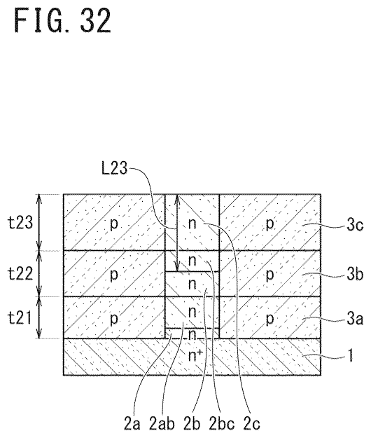

Next, a mask for ion implantation made of a photoresist film or the like is formed on the top surface side of the epitaxial growth layer 3c by photolithography. Openings of the mask for ion implantation are provided to be located over the respective n-type regions 2b. Next, a third step of implanting n-type impurity ions (also referred to below as “third ion implantation”) is executed by use of the mask for ion implantation. The ion implantation conditions for the third ion implantation are common to those for the first and second ion implantation steps. A range L23 of the third ion implantation (refer to FIG. 32) is greater than the thickness t23 of the epitaxial growth layer 3c to reach the upper part of the n-type regions 2b, but does not reach the bottom surface of the n-type regions 2b. The n-type impurity ions are thus implanted by the third ion implantation in the respective upper parts of the same n-type regions 2b as the implantation of the n-type impurity ions by the second ion implantation. The mask for ion implantation is then removed.

This step forms the n-type regions 2bc, which are each a semiconductor region of n-type including SiC, having a higher impurity concentration than the n-type regions 2b and doped with the n-type impurities accumulated together through the second and third ion implantation steps at the upper part of the n-type regions 2b, as illustrated in FIG. 32. This step also selectively forms the n-type regions 2c which are each a semiconductor region of n-type including SiC partly in the epitaxial growth layer 3c through the implantation of the n-type impurity ions by the third ion implantation. This step further selectively forms the p-type regions 3c which are each a semiconductor region of p-type including SiC in the rest of the epitaxial growth layer 3c not provided with the n-type regions 2c.

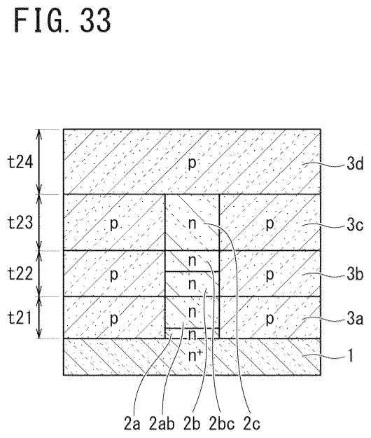

Next, as illustrated in FIG. 33, an epitaxial growth layer 3d which is a semiconductor region of p-type including SiC is epitaxially grown as a fourth layer (a fourth stage) on the top surface side of the n-type regions 2c and the p-type regions 3c. A thickness t24 of the epitaxial growth layer 3d is greater than the thickness t23 of each of the n-type regions 2c and the p-type regions 3c. The epitaxial growth layer 3d has an impurity concentration common to that of the n-type region 3c.

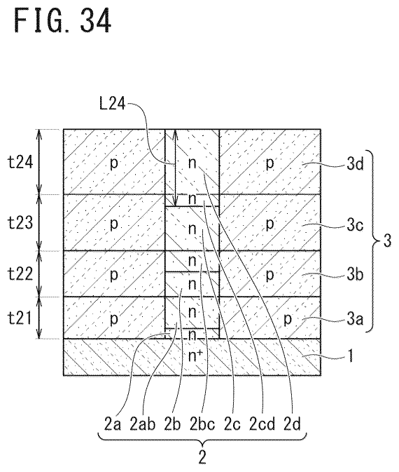

Next, a mask for ion implantation made of a photoresist film or the like is formed on the top surface side of the epitaxial growth layer 3d by photolithography. Openings of the mask for ion implantation are provided to be located over the respective n-type regions 2c. Next, a fourth step of implanting n-type impurity ions (also referred to below as “fourth ion implantation”) is executed by use of the mask for ion implantation. The ion implantation conditions for the fourth ion implantation are common to those for the first to third ion implantation steps. A range L24 of the fourth ion implantation (refer to FIG. 34) is greater than the thickness t24 of the epitaxial growth layer 3d to reach the upper part of the n-type regions 2c, but does not reach the bottom surface of the n-type regions 2c. The n-type impurity ions are thus implanted by the fourth ion implantation in the respective upper parts of the same n-type regions 2c as the implantation of the n-type impurity ions by the third ion implantation. The mask for ion implantation is then removed.

This step forms the n-type regions 2cd which are each a semiconductor region of n-type including SiC having a higher impurity concentration than the n-type regions 2c and doped with the n-type impurities accumulated together through the third and fourth ion implantation steps at the upper part of the n-type regions 2c, as illustrated in FIG. 34. This step also selectively forms the n-type regions 2d which are each a semiconductor region of n-type including SiC partly in the epitaxial growth layer 3d through the implantation of the n-type impurity ions by the fourth ion implantation. This step further selectively forms the p-type regions 3d which are each a semiconductor region of p-type including SiC in the rest of the epitaxial growth layer 3d not provided with the n-type regions 2d. The process as described above thus provides the drift layer (2, 3) with the SJ structure in which the n-type columns 2 and the p-type columns 3 are arranged parallel to each other.

The method of manufacturing the silicon carbide semiconductor device according to the fourth embodiment forms the drift layer (2, 3) with the SJ structure through the multi-step epitaxial process that repeatedly executes the epitaxial growth of the p-type epitaxial growth layers 3a to 3d and the ion implantation of the n-type impurity ions. The manufacturing method according to the present embodiment epitaxially grows the p-type epitaxial growth layers 3a to 3d with the thicknesses gradually increased as closer to the top layer, and uses the fixed depth for implanting the n-type impurity ions in the respective steps. This method can provide the drift layer (2, 3) with the SJ structure having a concentration gradient with p-rich on the top surface side and n-rich on the bottom surface side with no need to regulate the ion implantation conditions for the plural ion implantation steps.

### Other Embodiments

As described above, the present disclosure has been described according to the first to fourth embodiments, but it should not be understood that the description and drawings implementing a portion of this disclosure limit the present disclosure. Various alternative embodiments, examples, and operational techniques will be apparent to those skilled in the art from this disclosure.

For example, the semiconductor devices according to the first to fourth embodiments are each illustrated above with the trench-gate vertical MOSFET, but the respective embodiments may use a planar-gate MOSFET. The respective embodiments may also be applied to a case of using an insulated gate bipolar transistor (IGBT) including a p⁺-type collector region, instead of the n⁺-type drain region 1 in the MOSFET. Further, the respective embodiments may also be applied to a case of using a reverse conductive IGBT (RC-IGBT) or a reverse blocking IGBT (RB-IGBT), instead of a single IGBT.

Further, the semiconductor devices according to the first to fourth embodiments are each illustrated above with the silicon carbide (SiC) semiconductor devices using SiC, but are not limited to this case. For example, the respective semiconductor devices may include silicon (Si), or may include semiconductor (wide bandgap semiconductor) having a wider bandgap than Si, such as gallium nitride (GaN), gallium oxide (Ga₂O₃), diamond (C), and aluminum nitride (AlN).

Further, the semiconductor devices according to the first to fourth embodiments are each illustrated above with the case in which the charge balance of the drift layer (2, 3) in the depth direction is set such that the top surface side of the drift layer (2, 3) has p-rich and the bottom surface side has n-rich, but the charge balance of the drift layer (2, 3) in the depth direction may be set such that the top surface side of the drift layer (2, 3) has n-rich and the bottom surface side has p-rich. The case in which the top surface side of the drift layer (2, 3) has n-rich and the bottom surface side has p-rich can also provide a gradient in the charge balance of the drift layer (2, 3) in the depth direction, so as to increase a breakdown-voltage margin.

For example, the distribution of the impurity concentration in the n-type columns 2 of the drift layer (2, 3) in the depth direction is set to be constant, and the distribution of the impurity concentration in the p-type columns 3 in the depth direction is caused to vary such that the charge amount leans more toward the bottom surface of the drift layer (2, 3), so as to lead the top surface side of the drift layer (2, 3) to have n-rich and lead the bottom surface side to have p-rich. An example of a method of preparing the drift layer (2, 3) in this case repeatedly executes the epitaxial growth of the n-type epitaxial growth layers and the ion implantation of the p-type impurity ions, in which the plural epitaxial growth steps form the n-type epitaxial growth layers so as to have thicknesses gradually increased as closer to the top layer. The plural ion implantation steps can each use the fixed ion implantation conditions so as to execute the ion implantation of the p-type impurity ions with the common depth.

Alternatively, the distribution of the impurity concentration in the p-type columns 3 of the drift layer (2, 3) in the depth direction may be set to be constant, and the distribution of the impurity concentration in the n-type columns 2 in the depth direction may be caused to vary such that the charge amount leans more toward the top surface of the drift layer (2, 3), so as to lead the top surface side of the drift layer (2, 3) to have n-rich and lead the bottom surface side to have p-rich. Another example of the method of preparing the drift layer (2, 3) in this case repeatedly executes the epitaxial growth of the p-type epitaxial growth layers and the ion implantation of the n-type impurity ions, in which the plural epitaxial growth steps form the p-type epitaxial growth layers so as to have thicknesses gradually decreased as closer to the top layer. The plural ion implantation steps can each use the fixed ion implantation conditions so as to execute the ion implantation of the n-type impurity ions with the common depth.

As described above, the distribution of the impurity concentration in either the n-type columns 2 or the p-type columns 3 of the drift layer (2, 3) in the depth direction is set to be constant, and the distribution of the impurity concentration in the other ones of the drift layer (2, 3) in the depth direction is caused to vary. The sum of the charge amount of the other ones toward the top surface from the middle in the depth direction then only needs to vary to either increase or decrease more than the sum of the charge amount toward the bottom surface from the middle in the depth direction.

Further, the methods of manufacturing the semiconductor devices according to the first to fourth embodiments are each illustrated above with the case in which the plural epitaxial growth steps change the thicknesses of the respective epitaxial growth layers so as to be gradually increased or decreased as closer to the top layer, but the thicknesses of the epitaxial growth layers may be fixed in the respective epitaxial growth steps. In such a case, the plural ion implantation steps for implanting the impurity ions with the conductivity type opposite to that of the respective epitaxial growth layers only need to change the acceleration voltage to gradually decrease or increase, so as to provide the concentration gradient in the drift layer (2, 3) in the depth direction.

For example, the plural epitaxial growth steps may epitaxially grow the plural n-type epitaxial growth layers with the thicknesses common to each other. The plural ion implantation steps for implanting the p-type impurity ions then gradually increase the acceleration voltage to increase the range of the ion implantation as the number of times of the ion implantation increases, so as to lead the top surface side of the drift layer (2, 3) to have p-rich and lead the bottom surface side to have n-type rich. Alternatively, the plural ion implantation steps for implanting the p-type impurity ions may gradually decrease the acceleration voltage to decrease the range of the ion implantation as the number of times of the ion implantation increases, so as to lead the top surface side of the drift layer (2, 3) to have n-rich and lead the bottom surface side to have p-type rich.

The plural epitaxial growth steps may also epitaxially grow the plural p-type epitaxial growth layers with the thicknesses common to each other. The plural ion implantation steps for implanting the n-type impurity ions then gradually increase the acceleration voltage to increase the range of the ion implantation as the number of times of the ion implantation increases, so as to lead the top surface side of the drift layer (2, 3) to have n-rich and lead the bottom surface side to have p-type rich. Alternatively, the plural ion implantation steps for implanting the n-type impurity ions may gradually decrease the acceleration voltage to decrease the range of the ion implantation as the number of times of the ion implantation increases, so as to lead the top surface side of the drift layer (2, 3) to have p-rich and lead the bottom surface side to have n-type rich.

In addition, the configurations disclosed in the first to fourth embodiments can b combined together as appropriate within a range having no contradiction between the embodiments. It should be understood that the present disclosure can include various embodiments not disclosed herein. The technical scope of the present disclosure is thus defined only by the subject matter according to the appended claims reasonably derived from the foregoing descriptions.

What is claimed is:

1. A semiconductor device comprising:
a drift layer including p-type columns and n-type columns alternately and repeatedly arranged;
a base region provided on a top surface side of the drift layer;
a main region provided on a top surface side of the base region; and
an insulated gate electrode structure provided in contact with the base region and the main region,
wherein
a distribution of an impurity concentration of one of the p-type columns and the n-type columns in a depth direction is constant, and
an impurity concentration of another one of the p-type columns and the n-type columns at each of an upper end and a lower end in the depth direction is lower than an average concentration of the other one in the depth direction, and the other one of the p-type columns and the n-type columns has a peak concentration between the upper end and the lower end in the depth direction.

2. The semiconductor device of claim 1, wherein a width of each of the p-type columns and the n-type columns is constant in the depth direction.

3. The semiconductor device of claim 1, wherein the one of the p-type columns and the n-type columns is the n-type columns, and the other one is the p-type columns.

4. The semiconductor device of claim 3, wherein the n-type columns include a plurality of n-type regions having a common impurity concentration and having thicknesses gradually decreased as closer to a top layer.

5. The semiconductor device of claim 3, wherein the peak concentration is located toward a top surface from a middle of the p-type columns in the depth direction.

6. The semiconductor device of claim 1, wherein:
the semiconductor device includes trenches in which the insulated gate electrode structure is buried; and
the trenches are provided in a stripe state in a planar pattern.

7. The semiconductor device of claim 6, wherein the p-type columns are provided in a stripe state in a planar pattern parallel to the trenches between the respective trenches adjacent to each other.

8. The semiconductor device of claim 6, wherein the p-type columns are provided under the trenches.

9. The semiconductor device of claim 6, wherein the p-type columns are provided in a stripe state in a planar pattern so as to intersect with the trenches.

10. The semiconductor device of claim 3, wherein a sum of a charge amount of the type columns toward a top surface from a middle in the depth direction is greater than a sum of a charge amount of the p-type columns toward a bottom surface from the middle in the depth direction.

11. The semiconductor device of claim 1, wherein the one of the p-type columns and the n-type columns is the p-type columns, and the other one is the n-type columns.

12. The semiconductor device of claim 11, wherein the p-type columns include a plurality of p-type regions having a common impurity concentration and having thicknesses gradually increased as closer to a top layer.

13. The semiconductor device of claim 11, wherein a sum of a charge amount of the n-type columns toward a bottom surface from a middle in the depth direction is greater than a sum of a charge amount of the n-type columns toward a top surface from the middle in the depth direction.

14. A method of manufacturing a semiconductor device, the method comprising:
repeatedly executing epitaxial growth of epitaxial growth layers of a first conductivity-type and repeatedly executing ion implantation of impurities of a second conductivity-type so as to form a drift layer including n-type columns and p-type columns alternately and repeatedly arranged,
wherein
the repeatedly executing the epitaxial growth forms the epitaxial growth layers so as to have thicknesses gradually changed as closer to a top layer, and
the repeatedly executing the ion implantation implants the impurities to a common depth.

15. The method of manufacturing the semiconductor device of claim 14, wherein the repeatedly executing the ion implantation implants the same impurities at a common acceleration voltage.

16. The method of manufacturing the semiconductor device of claim 14, wherein the repeatedly executing the epitaxial growth forms the epitaxial growth layers with a common impurity concentration so as to have the thicknesses gradually decreased as closer to the top layer.

17. The method of manufacturing the semiconductor device of claim 14, wherein the repeatedly executing the ion implantation implants the impurities into a depth greater than or equal to a thickness of the respective epitaxial growth layers previously formed by the epitaxial growth.

18. The method of manufacturing the semiconductor device of claim 14, wherein the repeatedly executing the epitaxial growth forms the epitaxial growth layers with a common impurity concentration so as to have the thicknesses gradually increased as closer to the top layer.
